(19) United States
(12) Patent Application Publication
(10) Pub. No.: US 2015/0035166 A1
(43) Pub. Date: Feb. 5, 2015

(54) METHOD FOR MANUFACTURING A SEMICONDUCTOR COMPONENT AND STRUCTURE

(71) Applicant: Semiconductor Components Industries, LLC, Phoenix, AZ (US)

(72) Inventors: James P. Letterman, JR., Mesa, AZ (US); Phillip Celaya, Gilbert, AZ (US); Robert L. Marquis, Greene, RI (US)

(21) Appl. No.: 14/168,850

(22) Filed: Jan. 30, 2014

Related U.S. Application Data
(63) Continuation-in-part of application No. 13/692,514, filed on Dec. 3, 2012.
Application No. 13/692,514 is a continuation of application No. 13/190,922, filed on Jul. 26, 2011, now Pat. No. 8,324,026.
Application No. 13/190,922 is a division of application No. 12/362,142, filed on Jan. 29, 2009, now Pat. No. 8,071,427.

(51) Int. Cl. H01L 23/48; H01L 21/768

(52) U.S. Cl. CPC H01L 23/481; H01L 21/768
USPC 257/774; 438/618

(57) ABSTRACT

A semiconductor component having wettable leadframe lead surfaces and a method of manufacture. A leadframe having leadframe leads is embedded in a mold compound. The mold compound is separated to form singulated semiconductor components. A portion of at least one leadframe lead is exposed and an electrically conductive material is formed on the exposed portion using one of a vibratory plating device or a spouted bed electroplating device.

The present application is a continuation in part of prior U.S. patent application Ser. No. 13/692,514, filed on Dec. 3, 2012, which is a continuation of prior U.S. patent application Ser. No. 13/190,922, filed on Jul. 26, 2011, now U.S. Pat. No. 8,324,026, which is a divisional application of U.S. patent application Ser. No. 12/362,142, filed on Jan. 29, 2009, now U.S. Pat. No. 8,071,427 by Phillip Celaya et al., titled “Method for Manufacturing a Semiconductor Component and Structure Therefor,” which is hereby incorporated by reference in its entirety, and priority thereto for common subject matter is hereby claimed.

### TECHNICAL FIELD

The present invention relates, in general, to semiconductor components and, more particularly, to semiconductor component support structures.

### BACKGROUND

Semiconductor devices are typically manufactured from a semiconductor wafer. The wafer is diced to form chips or dice, which are mounted to a substrate such as a leadframe. The leadframe is then placed in a mold and a portion of the leadframe is encapsulated in a mold compound whereas another portion of the leadframe remains unencapsulated. The leadframe leads are plated with tin and cut to separate the substrate into individual semiconductor components. A drawback with this approach is that cutting the leadframe leads leaves exposed portions of the leadframe material. The exposed portions may not wet during surface mount processes leading to corrosion creep during extreme atmospheric conditions such as those within an automotive engine compartment. In addition, the exposed portions of the leadframes may form unreliable solder joints.

Accordingly, it would be advantageous to have a semiconductor component having leadframe leads with improved wettability and a method for manufacturing the semiconductor component. It would be of further advantage for the semiconductor component to be cost efficient to manufacture.

### BRIEF DESCRIPTION OF THE DRAWINGS

The present invention will be better understood from a reading of the following detailed description, taken in conjunction with the accompanying drawing figures, in which like reference characters designate like elements and in which:

FIG. 1 is an isometric view of a semiconductor component during manufacture in accordance with an embodiment of the present invention;

FIG. 2 is an isometric view the semiconductor component of FIG. 1 at a later stage of manufacture;

FIG. 3 is a cross-sectional view of the semiconductor component of FIG. 2 taken along section line 3-3 of FIG. 2;

FIG. 4 is a top view of a plurality of semiconductor components during manufacture in accordance with another embodiment of the present invention;

FIG. 5 is a bottom view of the plurality of semiconductor components of FIG. 4 at a later stage of manufacture;

FIG. 6 is a cross-sectional view of the plurality of semiconductor components of FIG. 5 taken along section line 6-6 at a later stage of manufacture;

FIG. 7 is a cross-sectional view of the plurality of semiconductor components of FIG. 6 at a later stage of manufacture;

FIG. 8 is a cross-sectional view of the plurality of semiconductor components of FIG. 7 at a later stage of manufacture;

FIG. 9 is a side view of the plurality of semiconductor components of FIG. 8 at a later stage of manufacture;

FIG. 10 is a top view of a plurality of semiconductor components during manufacture in accordance with another embodiment of the present invention;

FIG. 11 is a cross-sectional view of the plurality of semiconductor components of FIG. 10 taken along section line 11-11 at a later stage of manufacture;

FIG. 12 is a cross-sectional view of the plurality of semiconductor components of FIG. 11 at a later stage of manufacture;

FIG. 13 is a cross-sectional view of the plurality of semiconductor components of FIG. 12 at a later stage of manufacture;

FIG. 14 is a cross-sectional view of the plurality of semiconductor components of FIG. 13 at a later stage of manufacture;

FIG. 15 is a top view of a plurality of semiconductor components during manufacture in accordance with another embodiment of the present invention;

FIG. 16 is a bottom view of the plurality of semiconductor components of FIG. 15 at a later stage of manufacture;

FIG. 17 is a cross-sectional view of the plurality of semiconductor components of FIG. 16 taken along section line 17-17 at a later stage of manufacture;

FIG. 18 is a cross-sectional view of the plurality of semiconductor components of FIG. 17 at a later stage of manufacture;

FIG. 19 is a cross-sectional view of the plurality of semiconductor components of FIG. 18 at a later stage of manufacture;

FIG. 20 is a side view of the plurality of semiconductor components of FIG. 19 at a later stage of manufacture;

FIG. 21 is a cross-sectional view of a semiconductor component in accordance with another embodiment of the present invention;

FIG. 22 is an isometric view the semiconductor component during manufacture in accordance with another embodiment of the present invention;

FIG. 23 is a cross-sectional view of the semiconductor component of FIG. 22 taken along section line 23-23 of FIG. 22;

FIG. 24 is an isometric view the semiconductor component of FIG. 22 at a later stage of manufacture;

FIG. 25 is a cross-sectional view of the semiconductor component of FIG. 24 taken along section line 25-25 of FIG. 24;

FIG. 26 is an isometric view the semiconductor component during manufacture in accordance with another embodiment of the present invention;

FIG. 27 is a cross-sectional view of the semiconductor component of FIG. 26 taken along section line 27-27 of FIG. 26;

FIG. 28 is an isometric view the semiconductor component of FIG. 26 at a later stage of manufacture;

FIG. 29 is a cross-sectional view of the semiconductor component of FIG. 28 taken along section line 29-29 of FIG. 28;

FIG. 30 is an isometric view the semiconductor component during manufacture in accordance with another embodiment of the present invention;

FIG. 31 is a cross-sectional view of the semiconductor component of FIG. 30 taken along section line 31-31 of FIG. 30;

FIG. 32 is an isometric view the semiconductor component of FIG. 30 at a later stage of manufacture;

FIG. 33 is a cross-sectional view of the semiconductor component of FIG. 32 taken along section line 33-33 of FIG. 32;

FIG. 34 is an isometric view the semiconductor component during manufacture in accordance with another embodiment of the present invention;

FIG. 35 is a cross-sectional view of the semiconductor component of FIG. 34 taken along section line 35-35 of FIG. 34;

FIG. 36 is an isometric view the semiconductor component of FIG. 34 at a later stage of manufacture;

FIG. 37 is a cross-sectional view of the semiconductor component of FIG. 36 taken along section line 37-37 of FIG. 36;

FIG. 38 is an isometric view the semiconductor component during manufacture in accordance with another embodiment of the present invention;

FIG. 39 is a cross-sectional view of the semiconductor component of FIG. 38 taken along section line 39-39 of FIG. 38;

FIG. 40 is an isometric view the semiconductor component of FIG. 38 at a later stage of manufacture;

FIG. 41 is a cross-sectional view of the semiconductor component of FIG. 40 taken along section line 41-41 of FIG. 40;

FIG. 42 is an isometric view the semiconductor component during manufacture in accordance with another embodiment of the present invention; and

FIG. 43 is a cross-sectional view of the semiconductor component of FIG. 42 taken along section line 43-43 of FIG. 42.

### DETAILED DESCRIPTION

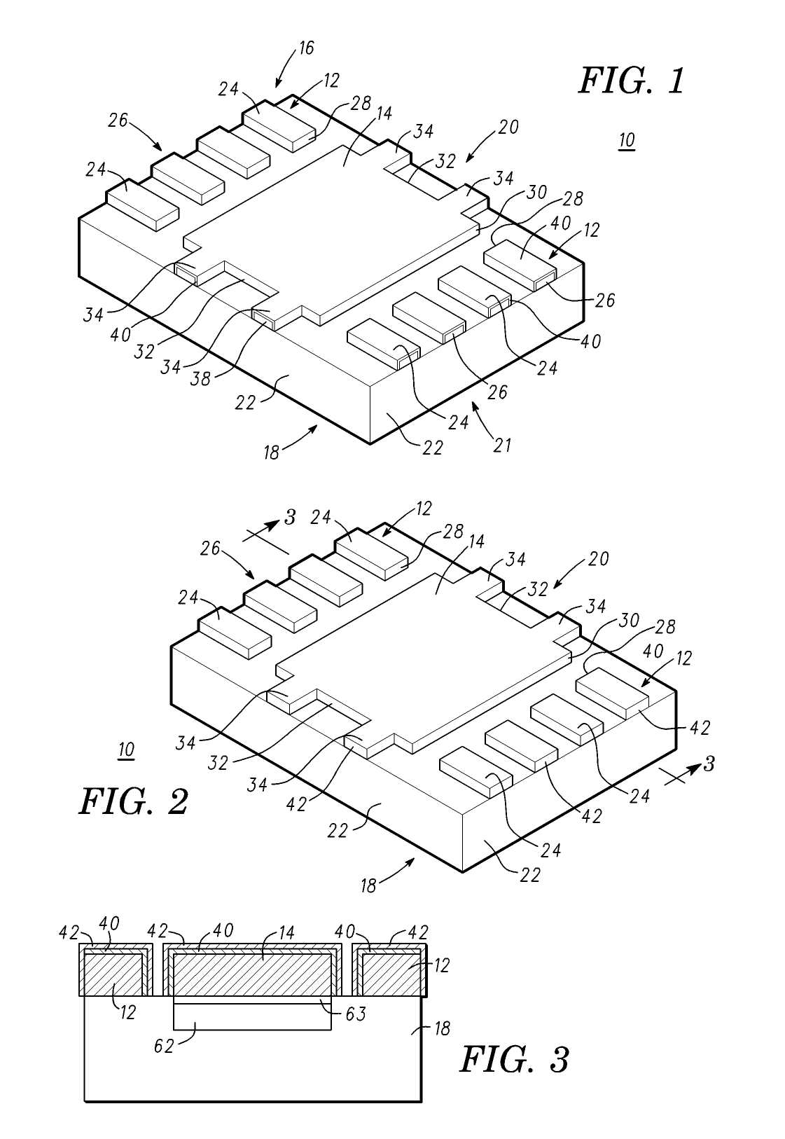

FIG. 1 is an isometric view of a semiconductor component 10 during manufacture in accordance with an embodiment of the present invention. What is shown in FIG. 1 are leadframe leads 12 and a leadframe flag 14 of a leadframe 16 partially embedded in a mold compound 18, which has sides 20 and 21 and edges or side surfaces 22. Leadframe leads 12 and leadframe flag 14 protrude or extend from side 20. Preferably, lead frame 16 is copper. However, this is not a limitation of the present invention. Other suitable materials for leadframe 16 include copper alloys, steel, iron, or the like. Leadframe leads 12 are shown as being rectangular cuboids having side surfaces 24 and end surfaces 26 and 28. Leadframe flag 14 is a rectangular cuboid having side surfaces 30, end surfaces 32, and extensions 34 extending from end surfaces 32. The shapes of the leadframe flag and leadframe leads are not limited to having a rectangular cuboid shape. Other shapes for the leadframe flag and leadframe leads include circular, oval, square, triangular, pentagonal, or any other geometric shape. Extensions 34 have end surfaces 38. A layer of electrically conductive material 40 is formed over leadframe leads 12 and flag 14. Electrically conductive material 40 may be tin, lead, solder, a combination of tin and lead, or the like. Electrically conductive material 40 is absent from end surfaces 26 of leadframe leads 12 and end surfaces 38 of extensions 34. Thus, end surfaces 26 and 38 are exposed regions of leadframe leads 12. When leadframe 16 is copper, end surfaces 26 and 38 are exposed regions of copper. By way of example, end surfaces 26 and 38 are exposed when semiconductor components 10 are separated or singulated from a leadframe strip (not shown) and may be referred to as outer edges of the leadframe lead.

Referring now to FIG. 2, an electrically conductive material 42 is formed on electrically conductive layer 40 and on end surfaces 26 and 38 using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 42 may be referred to as vibratory plated material or the spouted bed electroplated material when formed using a vibratory plating device or a spouted bed electroplating device, respectively, and may be formed over more than fifty percent and up to one hundred percent of the outer edge of the least one of the plurality of leads. Layers 40 and 42 are further illustrated in FIG. 3. In accordance with an embodiment, the material of electrically conductive layer 42 is tin. The material of electrically conductive layer 42 is not a limitation of the present invention. Other suitable materials for electrically conductive layer 42 include lead; solder; a combination of tin and lead; silver; nickel; a combination of nickel, lead, and gold; or the like. Similarly, the method for forming electrically conductive layer 42 is not a limitation of the present invention. Layer of electrically conductive material 42 may cover or partially cover surfaces 26 and 38. An advantage of forming layers of electrically conductive material 42 is that it forms a wettable material over surfaces 26 and 38.

FIG. 3 is a cross-sectional view of semiconductor component 10 taken along section line 3-3 of FIG. 2. FIG. 3 further illustrates leadframe leads 12, flag 14, and electrically conductive layers 40 and 42. For the sake of completeness, a semiconductor chip 62 is shown as being mounted to leadframe flag 14 through a die attach material 63.

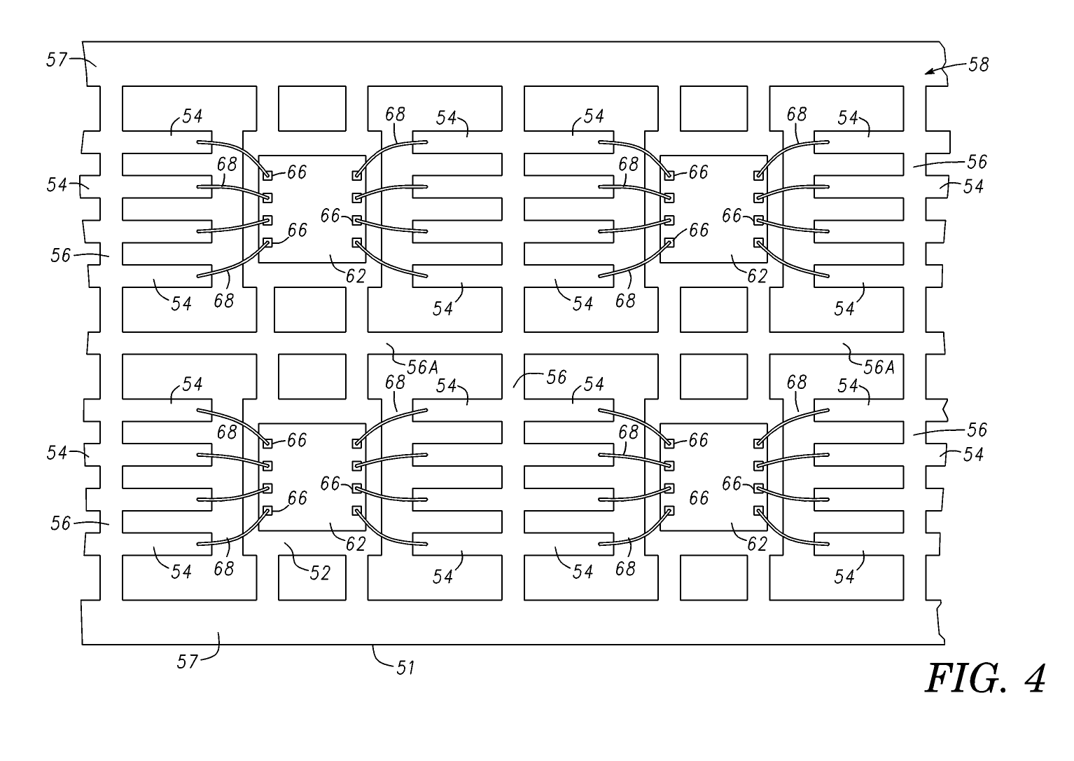

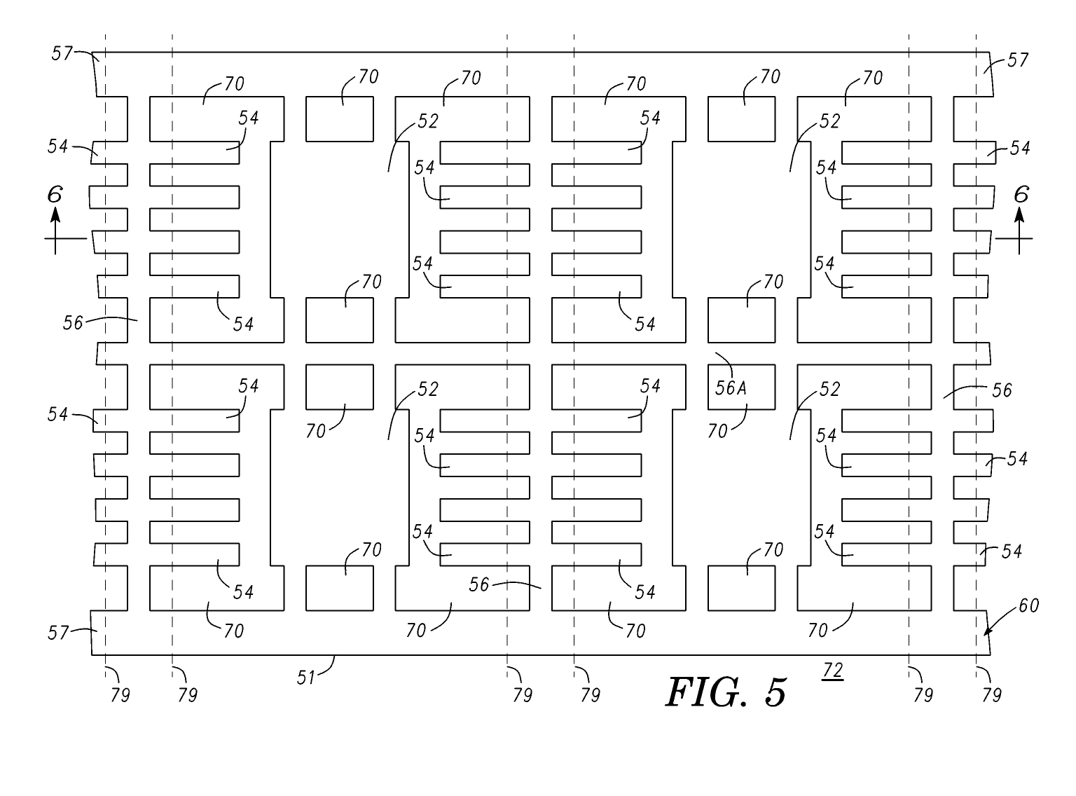

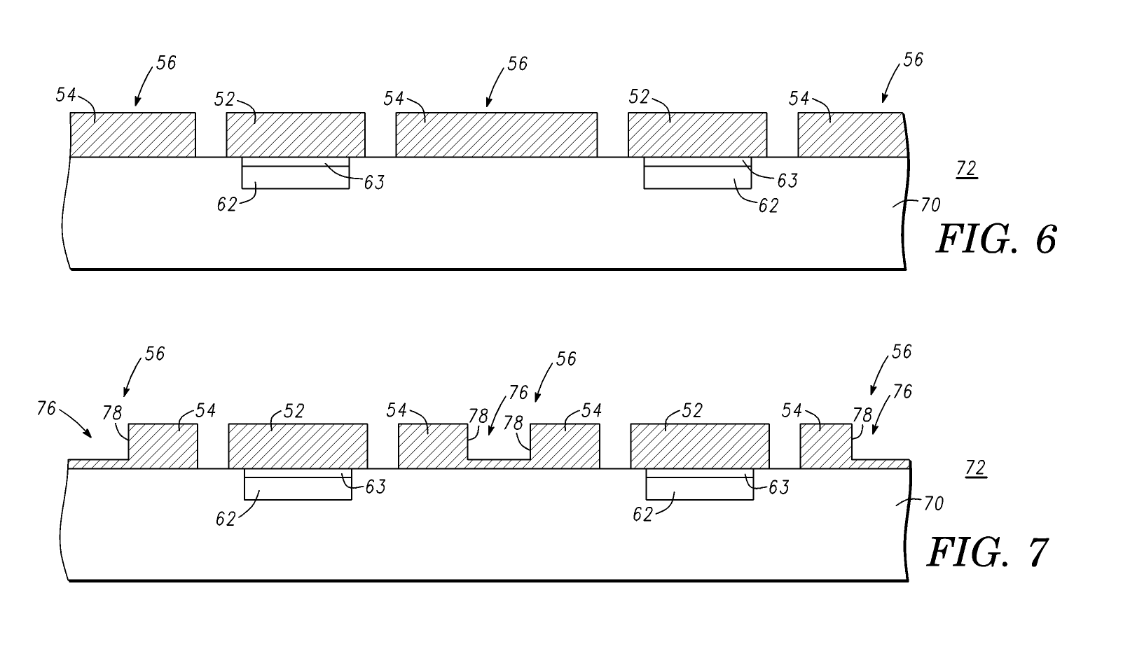

FIG. 4 is a top view of a portion of an electrically conductive support 51 having device or component receiving areas 52, interconnect structures 54, structural support members 56, 56A, and 57, and opposing sides 58 and 60 (opposing side 60 is illustrated in FIG. 5) used in the manufacture of semiconductor components 50 (shown in FIG. 9). Interconnect structures 54 are also referred to as electrical interconnect structures or electrically conductive interconnect structures. It should be noted that the term top view is used for the sake of clarity and to distinguish the side of electrically conductive support 51 to which one or more active circuit elements or one or more passive circuit elements is mounted. In accordance with an embodiment, electrically conductive support 51 is a leadframe, interconnect structures 52 are flags, interconnect structures 54 are leadframe leads, support members 56 and 56A are tie bars, and support members 57 are rails. By way of example, semiconductor chips or dice 62 are coupled to side 58 of leadframe 51 through a die attach material 63 (shown in FIG. 6). More particularly, a semiconductor chip 62 is mounted to each flag 52 through the die attach material. Semiconductor chips 62 have bond pads 66 that are coupled to corresponding leadframe leads 54 through bond wires 68. Bond wires are also referred to as wirebonds. The number of flags and leadframe leads and their shapes are not limitations of the present invention. Although semiconductor chips 62 have been described as being mounted to flags 52, the embodiments are not limited in this respect. Passive circuit elements such as resistors, inductors, and capacitors as well as active circuit elements such as semiconductor chips comprising transistors may be coupled to or mounted on leadframe 51 in place of or in addition to semiconductor chips 62.

Referring now to FIG. 5, a bottom view of a portion of leadframe 51 after a mold compound 70 has been formed over semiconductor chips 62 and wirebonds 68 to form a molded leadframe strip 72 is shown. It should be understood that mold compound 70 is formed over side 58, i.e., the top side, leaving side 60 substantially free of mold compound and that FIG. 5 is a bottom view of leadframe 51. It should be further understood that referring to the views shown in the figures as top views and bottom views and the designation of a view as being a top view or a bottom view is merely to facilitate describing embodiments of the present invention. Broken lines 79 indicate where portions of leadframe leads 54 will be separated and exposed. Broken lines 79 also indicate the regions in which tie bars 56 are removed. Separating and exposing leadframe leads 54 and removing tie bars 56 are further described with reference to FIG. 7.

FIG. 6 is a cross-sectional view of molded leadframe strip 72 taken along section line 6-6 of FIG. 5. FIG. 6 illustrates portions of leadframe flags 52, leadframe leads 54, die attach material 63, and semiconductor chips 62.

FIG. 7 is a cross-sectional view of molded leadframe strip 72 shown in FIG. 6 at a later stage of manufacture. What is shown in FIG. 7 is leadframe 51 after portions have been removed. More particularly, portions of leadframe leads 54 and tie bars 56 are removed to form cavities 76 having sidewalls 78. By way of example, the portions of leadframe leads 54 and tie bars 56 are removed by partially sawing into leadframe leads 54 and tie bars 56. Preferably, the thickness of leadframe leads 54 and tie bars 56 that are removed ranges from about 50 percent (%) to 100% of the thicknesses of leadframe leads 54 and tie bars 56. However, the thicknesses of leadframe leads 54 and tie bars 56 that are removed may be less than 50% and equal to or greater than 100% of their thicknesses. In accordance with an embodiment, about three-fourths of the thickness of leadframe leads 54 and tie bars 56 is removed. Suitable techniques for removing the portions of leadframe leads 54 include sawing, cutting, etching, stamping, punching, or the like. The regions at which the portions of leadframe leads 54 and tie bars 56 are removed are shown in FIG. 5 and identified by broken lines 79.

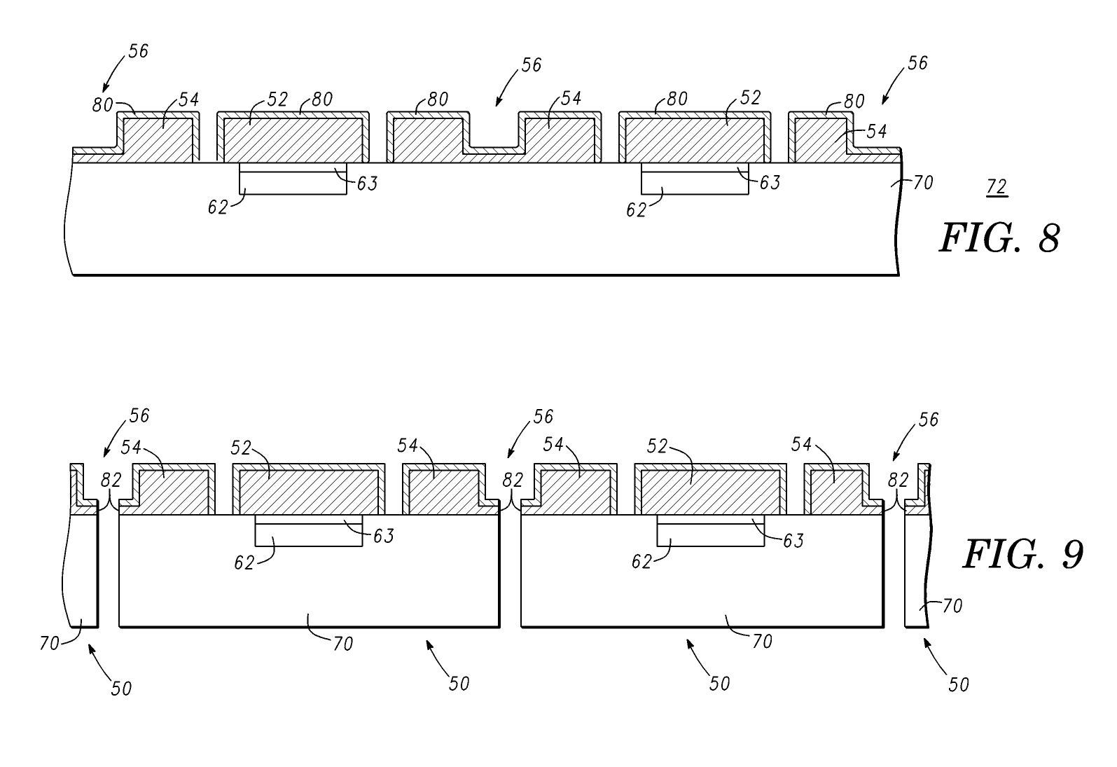

Referring now to FIG. 8, a layer of electrically conductive material 80 having a thickness ranging from about 0.5 microinches (12.7 nanometers) to about 3,000 microinches (76.2 micrometers) is formed on leadframe leads 54, including the portions of leadframe leads 54 within cavities 76. In accordance with an embodiment, electrically conductive material 80 is tin formed by an electroplating process using a spouted bed electroplating device or a vibratory plating device. Electrically conductive material 80 may be referred to as vibratory plated material or the spouted bed electroplated material when formed using a vibratory plating device or a spouted bed electroplating device, respectively, and may be formed over more than fifty percent and up to one hundred percent of an outer edge of the least one of the leadframe leads. The type of electrically conductive material and the method for forming the electrically conductive material are not limitations of the present invention. Other suitable materials for electrically conductive layer 80 include silver; nickel; a combination of nickel, lead, and gold; or the like. Similarly, the method for forming electrically conductive layer 80 is not a limitation of the present invention.

Although the examples for the material for electrically conductive layer 80 have been metals, this is not a limitation of the present invention. For example, layer 80 may be a conductive epoxy. Alternatively, an anti-oxidizing coating or agent may be formed over leadframe leads 54 and on the exposed portions of leadframe leads 54. These types of coatings are electrically non-conductive materials that inhibit the oxidation of metals such as copper at room temperature. During the formation of solder over leadframe leads 54, the anti-oxidizing coating evaporates allowing solder to form on the exposed portions of leadframe leads 54. The anti-oxidizing coating leaves a clean wettable copper surface after it has evaporated to which solder can adhere.

Referring now to FIG. 9, portions of leadframe leads 54 and tie bars 56 remaining in cavities 76 are removed exposing sidewall portions 82 of leadframe leads 54 and portions of mold compound 70, and singulating molded leadframe strip 72 into individual semiconductor components 50. In embodiments in which cavities 76 are formed using a sawing process and molded leadframe strip 72 is singulated using a sawing process, preferably the width of the saw blade used to singulate molded leadframe strip 72 is less than the width of the saw blade used to form cavities 76. The remaining portions of electrically conductive layer 80 provide a wettable material over portions of the surfaces of leadframe leads 54.

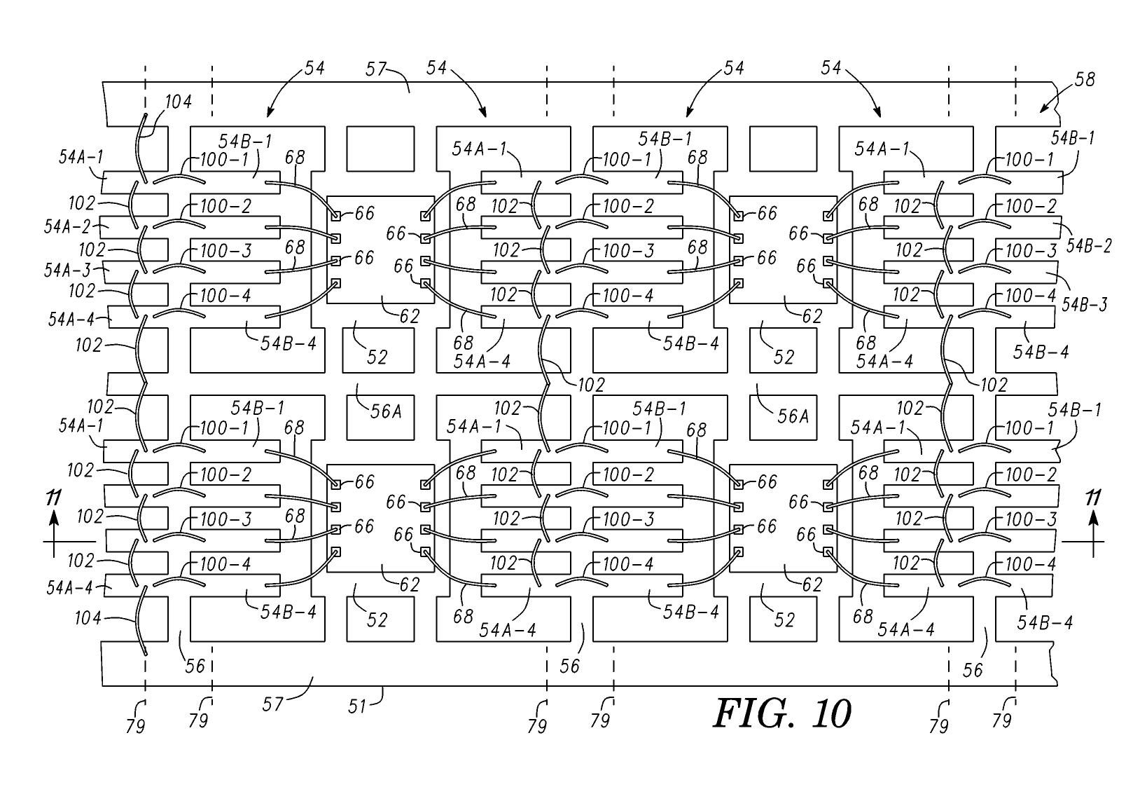

FIG. 10 is a top view of a leadframe 51 having flags 52, leadframe leads 54, tie bars 56 and 56A, and opposing sides 58 and 60. Leadframe leads 54 are comprised of leadframe leads 54A-1, 54B-1, 54A-2, 54B-2, 54A-3, 54B-3, 54A-4, and 54B-4, wherein leadframe leads 54A-1 and 54B-1 are on directly opposite sides of tie bars 56, leadframe leads 54A-2 and 54B-2 are on directly opposite sides of tie bars 56, leadframe leads 54A-3 and 54B-3 are on directly opposite sides of tie bars 56, and leadframe leads 54A-4 and 54B-4 are on directly opposite sides of tie bars 56. Semiconductor chips or dice 62 are coupled to side 58 of leadframe 51 through a die attach material 63. More particularly, a semiconductor chip 62 is mounted to each flag 52 through die attach material 63. Semiconductor chips 62 have bond pads 66 that are coupled to corresponding leadframe leads 54 through bond wires 68. Bond wires are also referred to as wirebonds. The number of flags 52 and leadframe leads 54 per leadframe are not limitations of the present invention.

Wirebonds 100-1, 100-2, 100-3, and 100-4 are formed to electrically couple leadframe leads 54A-1, 54A-2, 54A-3, and 54A-4 with leadframe leads 54B-1, 54B-2, 54B-3, and 54B-4, respectively. Wirebonds 102 are formed to electrically couple leadframe leads 54A-1, 54A-2, 54A-3, and 54A-4 to each other and wirebonds 104 are formed to electrically couple leadframe leads 54A-1, 54A-2, 54A-3, 54A-4, 54B-1, 54B-2, 54B-3, and 54B-4 to at least one of rails 57. Alternatively, wirebonds 102 can be formed to electrically couple leadframe leads 54B-1, 54B-2, 54B-3, and 54B-4 to each other. Wirebonds 100-1, 100-2, 100-3, 100-4, 102, and 104 form electrical connections between leadframe leads 54 and rails 57 during the plating process. The use of wirebonds for electrically connecting leadframe leads 54, tie bars 56, and rails 57 is not a limitation of the present invention. For example, conductive clips may be used to electrically connect leadframe leads 54, tie bars 56, and rails 57.

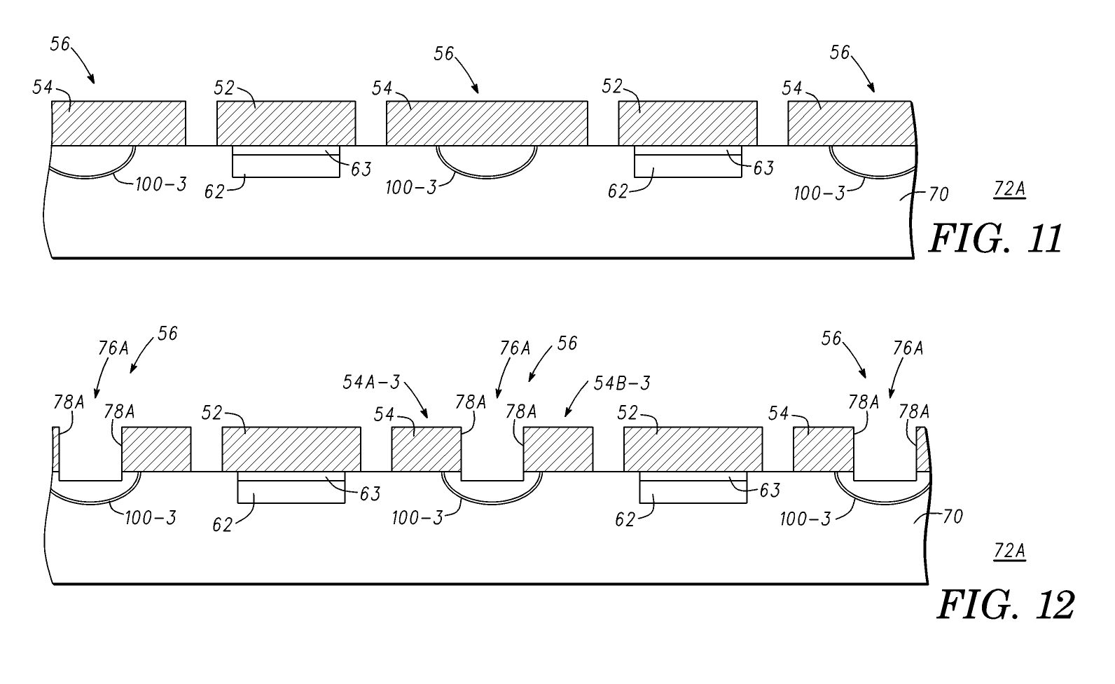

Like semiconductor components 10 and 50, a mold compound 70 (shown in FIGS. 11-14) is formed over semiconductor chips 62 and wirebonds 68, 100-1, 100-2, 100-3, 100-4, 102, and 104 to form a molded leadframe strip 72A (shown in FIGS. 11-13) that is similar to molded leadframe strip 72. It should be noted that a bottom view of a molded leadframe strip for semiconductor component 150 is similar to the bottom view of molded leadframe strip 72 shown in FIG. 5. A bottom view of the molded leadframe strip is similar to the bottom view shown in FIG. 5. As described above, referring to the views shown in the figures as top views and bottom views and the designation of a view as being a top view or a bottom view is merely to facilitate describing embodiments of the present invention.

FIG. 11 is a cross-sectional view of molded leadframe strip 72A taken along the region shown by section line 11-11 of FIG. 10 but at a later step than that shown in FIG. 10. FIG. 11 illustrates portions of leadframe flags 52, leadframe leads 54, die attach material 63, semiconductor chips 62, and wirebonds 100-3.

FIG. 12 is a cross-sectional view of molded leadframe strip 72A shown in FIG. 11 but at a later stage of manufacture than the molded leadframe strip shown in FIG. 11. What is shown in FIG. 12 is molded leadframe strip 72A after portions of leadframe 51 and mold compound 70 have been removed. More particularly, portions of leadframe leads 54 and mold compound 70 are removed to form cavities 76A having sidewalls 78A. By way of example, the portions of leadframe leads 54 are removed by sawing into leadframe leads 54, tie bars 56, and mold compound 70. The method for removing leadframe leads 54, tie bars 56 and mold compound 70 is not a limitation of the present invention. Other suitable techniques for removing the portions of leadframe leads 54 include sawing, cutting, etching, stamping, punching, or the like. The regions at which the portions of leadframe leads 54, tie bars 56, and rails 57 are removed are identified by broken lines 79 shown in FIG. 10.

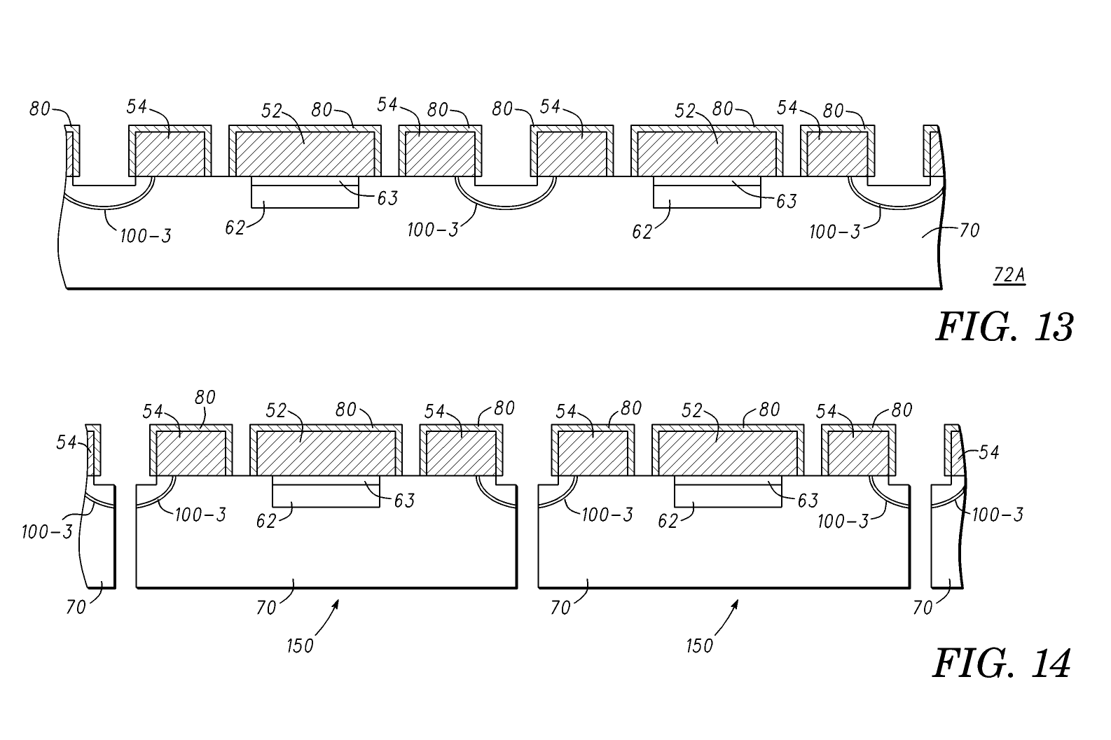

Referring now to FIG. 13, a layer of electrically conductive material 80 having a thickness ranging from about 0.5 microinches (12.7 nanometers) to about 3,000 microinches (76.2 micrometers) is formed on leadframe leads 54, including the portions of leadframe leads 54 within cavities 76A. In accordance with an embodiment, electrically conductive material 80 is tin formed by an electroplating process using a spouted bed electroplating device or a vibratory plating device and may be formed over more than fifty percent and up to one hundred percent of an outer edge of the least one of the leadframe leads. Electrically conductive material 80 may be referred to as vibratory plated material or the spouted bed electroplated material when formed using a vibratory plating device or a spouted bed electroplating device, respectively, and may be formed over more than fifty percent and up to one hundred percent of an outer edge of the least one of the leadframe leads. The type of electrically conductive material and the method for forming the electrically conductive material are not limitations of the present invention. Other suitable materials for electrically conductive layer 80 include silver; nickel; a combination of nickel, lead, and gold; or the like. Similarly, the method for forming electrically conductive layer 80 is not a limitation of the present invention.

As discussed above, electrically conductive layer 80 is not limited to being a metal, but can be a conductive epoxy or an anti-oxidizing coating or agent formed over leadframe leads 54 and on the exposed portions of leadframe leads 54. These types of coatings are electrically non-conductive materials that inhibit the oxidation of metals such as copper at room temperature. During the formation of solder over leadframe leads 54, the anti-oxidizing coating evaporates allowing solder to form on the exposed portions of leadframe leads 54. The anti-oxidizing coating leaves a clean wettable copper surface after it has evaporated to which solder can adhere.

Referring now to FIG. 14, portions of leadframe leads 54 and tie bars 56 remaining in cavities 76A and portions of mold compound 70 are removed forming sidewalls from mold compound 70 and singulating molded leadframe strip 72A into individual semiconductor components 150, i.e., the portions of mold compound 70 exposed by removing the portions of leadframe leads 54 and tie bars 56 are removed to singulate molded leadframe strip 72A into individual semiconductor components 150. In addition, wire bonds 100-1, 100-2, 100-3, 100-4, 102, and 104 are cut, opened, or separated. It should be noted that in embodiments in which wire bonds 102 and 104 are opened using a sawing or cutting process, wire bonds 102 and 104 are cut in a direction substantially perpendicular to wire bonds 100-1, 100-2, 100-3, 100-4. The remaining portions of electrically conductive layer 80 provide a wettable material over surfaces of leadframe leads 54.

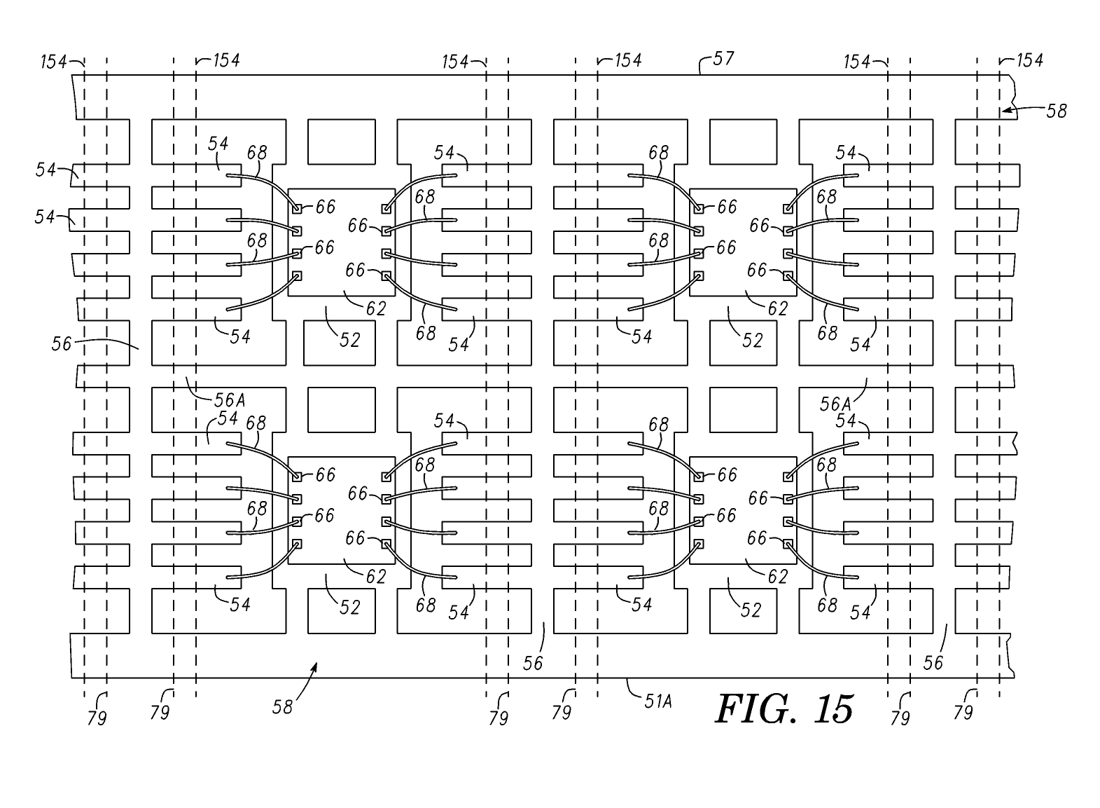

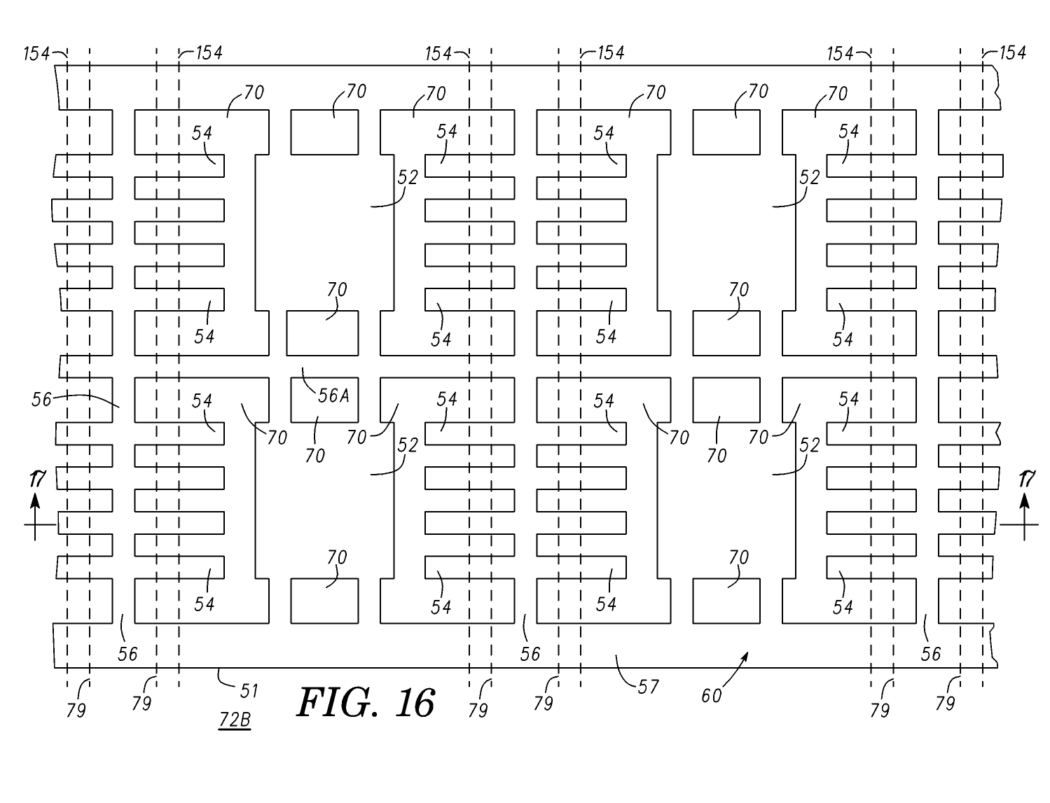

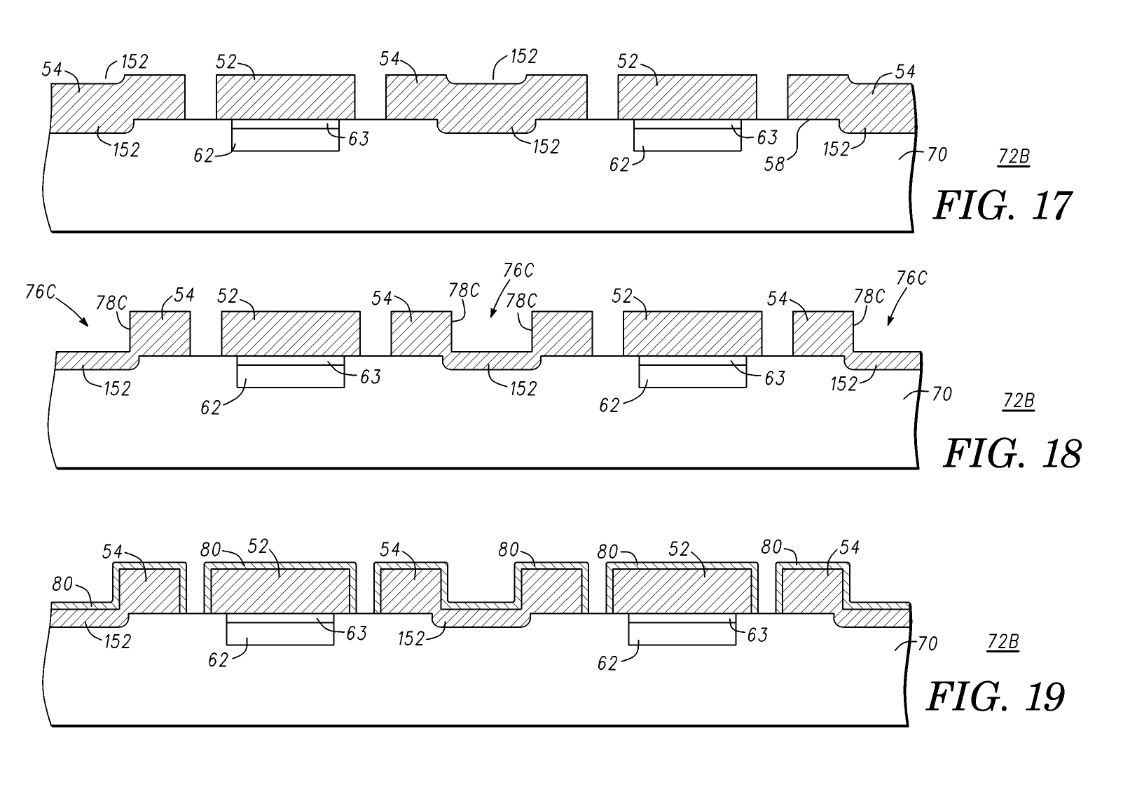

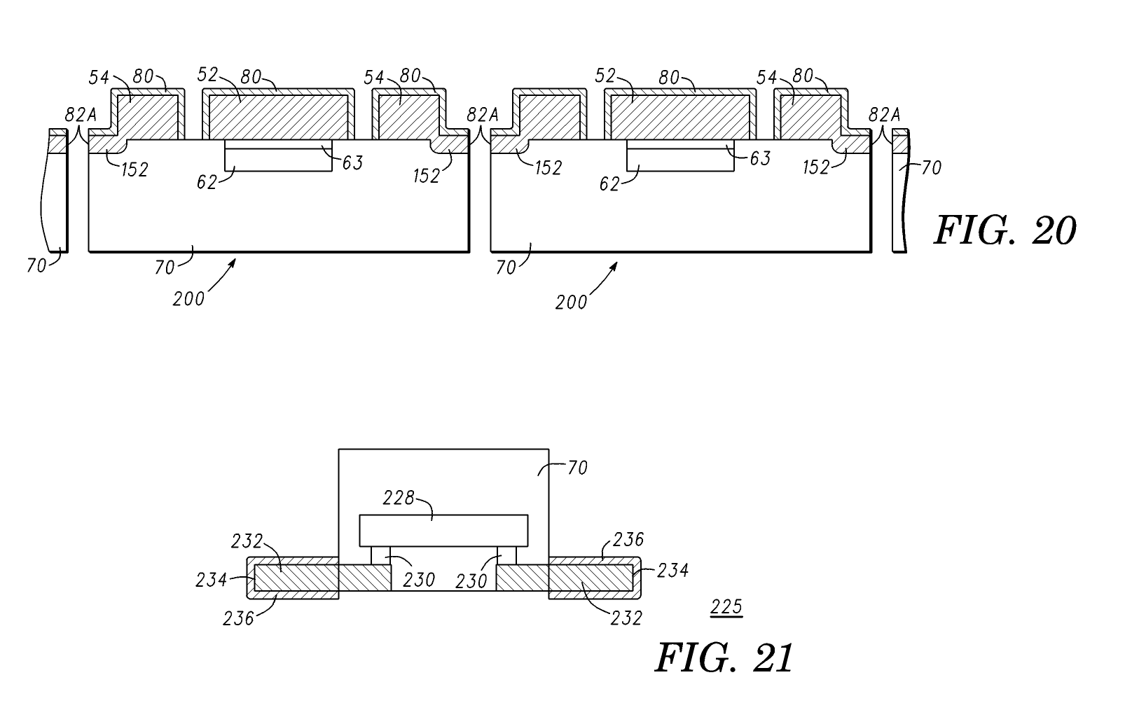

FIG. 15 is a top view of a portion of a leadframe 51A having a flag 52, leadframe leads 54, tie bars 56 and 56A, rails 57, and opposing sides 58 and 60 (opposing side 60 is illustrated in FIG. 16) used in the manufacture of semiconductor components 200 (shown in FIG. 20). Leadframe 51A is similar to leadframe 51 described with reference to FIG. 4 except that dimples 152 are formed in tie bars 56. Because of this difference, the reference character “A” has been appended to reference character 51. Dimples 152 may be formed by stamping the tie bars of leadframe 51A. The locations of dimples 152 are illustrated by broken lines 154 in FIG. 14. Dimples 152 are shown in FIGS. 17-20. Semiconductor chips or dice 62 are coupled to side 58 of leadframe 51A and bond pads 66 are coupled to corresponding leadframe leads 54 through bond wires 68 as described with reference to FIG. 4. Alternatively and as discussed with reference to FIG. 3, passive circuit elements such as resistors, capacitors, and inductors or other active circuit elements may be coupled to or mounted on leadframe 51A in place of or in addition to semiconductor chips 62.

Referring now to FIG. 16, a bottom view of a portion of leadframe 51 after a mold compound 70 has been formed over semiconductor chips 62 and wirebonds 68 to form a molded leadframe strip 72B is shown. Broken lines 154 indicate where dimples 152 are formed in leadframe 51A. It should be understood that mold compound 70 is formed over side 58, i.e., the top side, leaving side 60 substantially free of mold compound and that FIG. 16 is a bottom view of leadframe 51A. It should be further understood that referring to the views shown in the figures as top views and bottom views and the designation of a view as being a top view or a bottom view is merely to facilitate describing embodiments of the present invention. Broken lines 79 indicate where portions of leadframe leads 54 are separated and exposed. Broken lines 79 also indicate the regions in which tie bars 56 are removed. The acts of separating and exposing leadframe leads 54 and removing tie bars 56 are further described with reference to FIG. 18.

A mold compound 70 is formed over semiconductor chips 62 and wirebonds 68 to form a molded leadframe strip 72B as described with reference to FIG. 5. Like FIG. 5, FIG. 16 is a bottom view of molded leadframe strip 72B. The locations of dimples 152 are illustrated by broken lines 154. As discussed above, dimples 152 are shown with reference to FIGS. 17-20. Broken lines 79 indicate where portions or regions of leadframe leads 54 are separated and exposed.

FIG. 17 is a cross-sectional view of molded leadframe strip 72B taken along section line 17-17 of FIG. 16. FIG. 17 illustrates portions of leadframe flags 52, leadframe leads 54, die attach material 63, semiconductor chips 62, and dimples 152.

FIG. 18 is a cross-sectional view of molded leadframe strip 72B shown in FIG. 17 at a later stage of manufacture. What is shown in FIG. 18 is molded leadframe strip 72B after portions of leadframe 51A have been removed to form cavities 76C having sidewalls 78C. By way of example, the portions of leadframe leads 54 are removed by partially sawing into leadframe leads 54 and tie bars 56. Preferably, the thicknesses of leadframe leads 54 and tie bars 56 that are removed is less than about 100% of the thickness of leadframe leads 54. In accordance with an embodiment, about three-fourths of the thicknesses of leadframes 54 and tie bars 56 are removed. Suitable techniques for removing the portions of leadframe leads 54 include sawing, cutting, etching, stamping, punching, or the like. The regions at which the portions of leadframe leads 54, tie bars 56, and rails 57 are removed are identified by broken lines 79 shown in FIGS. 15 and 16.

Referring now to FIG. 19, a layer of electrically conductive material 80 having a thickness ranging from about 0.5 microinches (12.7 nanometers) to about 3,000 microinches (76.2 micrometers) is formed on leadframe leads 54, including the portions of leadframe leads 54 within cavities 76C. In accordance with an embodiment, electrically conductive material 80 is tin formed by an electroplating process in a spouted be electroplating device or a vibratory plating device. Electrically conductive material 80 may be referred to as vibratory plated material or the spouted bed electroplated material when formed using a vibratory plating device or a spouted bed electroplating device, respectively, and may be formed over more than fifty percent and up to one hundred percent of an outer edge of the least one of the leadframe leads. The type of electrically conductive material and the method for forming the electrically conductive material are not limitations of the present invention. Other suitable materials for electrically conductive layer 80 include silver; nickel; a combination of nickel, lead, and gold; or the like. Similarly, the method for forming electrically conductive layer 80 is not a limitation of the present invention.

As discussed above, electrically conductive layer 80 is not limited to being a metal, but can be a conductive epoxy or an anti-oxidizing coating or agent formed over leadframe leads 54 and on the exposed portions of leadframe leads 54. These types of coatings are electrically non-conductive materials that inhibit the oxidation of metals such as copper at room temperature. During the formation of solder over leadframe leads 54, the anti-oxidizing coating evaporates allowing solder to form on the exposed portions of leadframe leads 54. The anti-oxidizing coating leaves a clean wettable copper surface after it has evaporated to which solder can adhere.

Referring now to FIG. 20, portions of leadframe leads 54 and tie bars 56 remaining in cavities 76C are removed exposing sidewall portions of electrically conductive layer 80, sidewall portions 82A of leadframe leads 54, and portions of mold compound 70, and singulating molded leadframe strip 72B into individual semiconductor components 200. In embodiments in which cavities 76C are formed using a sawing process and molded leadframe strip 72B are singulated using a sawing process, preferably the width of the saw blade used to singulate molded leadframe strip 72B is less than the width of the saw blade used to form cavities 76C. The remaining portions of electrically conductive layer 80 provide a wettable material over surfaces of leadframe leads 54.

Referring now to FIG. 21, a cross-sectional view of a semiconductor component 225 is illustrated. Semiconductor component 225 includes a semiconductor chip 228 having bond pads 230 mounted to leadframe leads 232 and protected by a mold compound 70. A material 236 is formed on edges 234 of leadframe leads 232 that were exposed after singulation. Material 236 may be an electrically conductive material or an anti-oxidizing material. Although material 236 is shown as covering all of edges 234, this is not a limitation of the present invention. Material 236 may cover less than the entirety of edges 234. It should be noted that flags are absent from component 225.

In accordance with another embodiment, a semiconductor component such as, for example semiconductor component 10, 50, 150, 200, or 225, is within an engine compartment of an automobile.

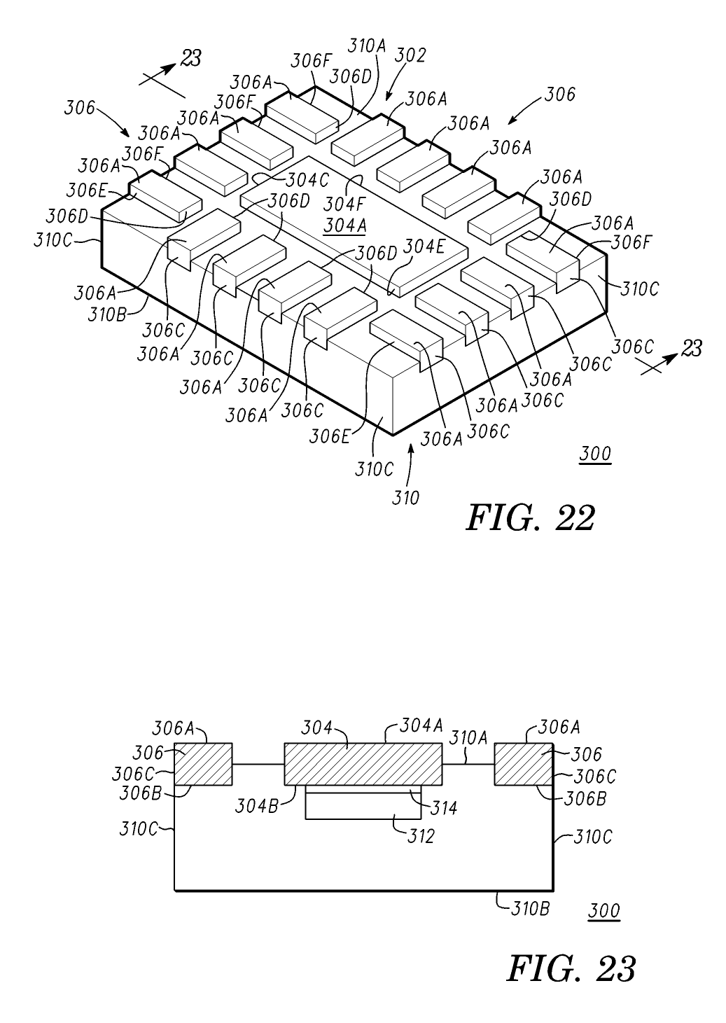

FIG. 22 is an isometric view of a semiconductor component 300 during manufacture in accordance with another embodiment of the present invention. FIG. 23 is a cross-sectional view of semiconductor component 300 taken along section line 23-23 of FIG. 22. For the sake of clarity, FIGS. 22 and 23 will be described together. FIGS. 22 and 23 illustrate a portion of an electrically conductive support 302 that includes a device or component receiving structure 304 and interconnect structures 306 partially embedded in a mold compound 310. In accordance with an embodiment, electrically conductive support 302 is a portion of a leadframe such as, for example, leadframe 51 described with reference to FIG. 4. Device receiving structure 304 has opposing major surfaces 304A and 304B and minor surfaces 304C, 304D, 304E, and 304F. Minor surfaces 304C-304F may be referred to as edges. Major surface 304B serves as a device attach or device receiving area. Interconnect structures 306 have opposing major surfaces 306A and 306B and minor surfaces 306C, 306D, 306E, and 306F. Surfaces 306C are on one side of semiconductor component 300 and surfaces 306D are on a side opposite to the side on which surfaces 306C are located. In accordance with embodiments in which electrically conductive support 302 is a leadframe, device receiving structure 304 may be referred to as a flag, a die attach paddle, or a die attach pad, and interconnect structures 306 may be referred to as leadframe leads. The distance between major surface 304A and major surface 304B is referred to as a thickness of device receiving structure 304. The distance between major surface 306A and major surface 306B may be referred to as the thickness of leadframe lead 306. Electrically conductive support 302 is embedded in a mold compound 310, which mold compound 310 has major surfaces 310A and 310B and minor surfaces 310C. In accordance with an embodiment, at least 20 percent (%) of the thickness of electrically conductive support 302 is embedded in mold compound 310. In accordance with another embodiment, at least 50% of the thickness of electrically conductive support 302 is embedded in mold compound 310. In accordance with yet another embodiment, at least 90% of the thickness of electrically conductive support 302 is embedded in mold compound 310. It should noted that the amount of material embedded in mold compound 310 should be enough to secure conductive support 302 in mold compound 310. It should further noted that surfaces 304A and 306A are vertically spaced apart from surface 310A.

FIG. 23 further illustrates a semiconductor chip or die 312 mounted to device receiving area 304B of die attach paddle 304. More particularly, a die attach material 314 is deposited on device receiving area 304B and a semiconductor chip 312 is positioned on die attach material 314 so that semiconductor chip 312 is mounted to device receiving area 304B of die attach paddle through a die attach material 314.

It should be understood that semiconductor component 300 is a single component that has been singulated from a molded leadframe strip (described with reference to FIG. 20) using a sawing technique and may be referred to as outer edges of the interconnect structure. Thus, surfaces 306C of interconnect structures 306 are substantially planar with corresponding minor surfaces 310C of mold compound 310.

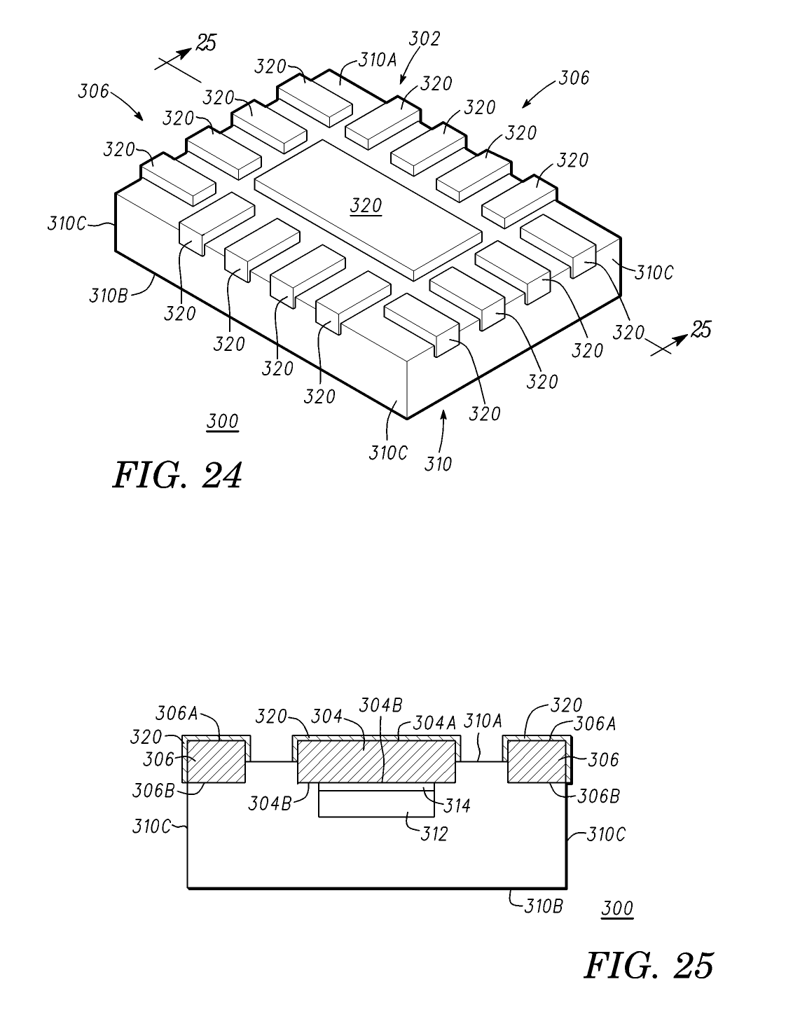

FIG. 24 is an isometric view of semiconductor component 300 shown in FIGS. 22 and 23 at a later stage of manufacture. FIG. 25 is a cross-sectional view of semiconductor component 300 taken along section line 25-25 of FIG. 24. For the sake of clarity, FIGS. 24 and 25 will be described together. A layer of electrically conductive material 320 is formed on the exposed portions of device receiving structure 304 and interconnect structures 306, i.e., on the exposed portions of surfaces 304A and 304C-304F. Electrically conductive material 320 is not formed on the portions of device receiving area 304 and interconnect structures 306 within or surrounded by mold compound 310. Electrically conductive layers 320 are formed using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 320 may be referred to as a spouted bed electroplated material when formed using a spouted bed electroplating device for its formation or a vibratory plated material when formed using a vibratory plating device for its formation. By way of example, the spouted bed electroplated material or the vibratory plated material may have a thickness at least about 2 micrometers (μm) and may be formed on up to one hundred percent of a surface 306C of least one of the interconnect structures 306. Layers 320 are further illustrated in FIG. 25, which figure shows that after plating, layers 320 on surface 306C extend out of the plane formed by surfaces 306C and 310C.

In accordance with an embodiment, the material of electrically conductive layer 320 is tin. The material of electrically conductive layer 320 is not a limitation of the present invention. Other suitable materials for electrically conductive layer 320 include lead; solder; a combination of tin and lead; silver; nickel; a combination of nickel, lead, and gold; or the like. Similarly, the method for forming electrically conductive layer 320 is not a limitation of the present invention. Layer of electrically conductive material 320 may cover or partially cover surfaces 306C-306F. An advantage of forming layer of electrically conductive material 320 is that it forms a wettable material over edges or surface 306C-306F that is useful in mounting the semiconductor component in end user applications.

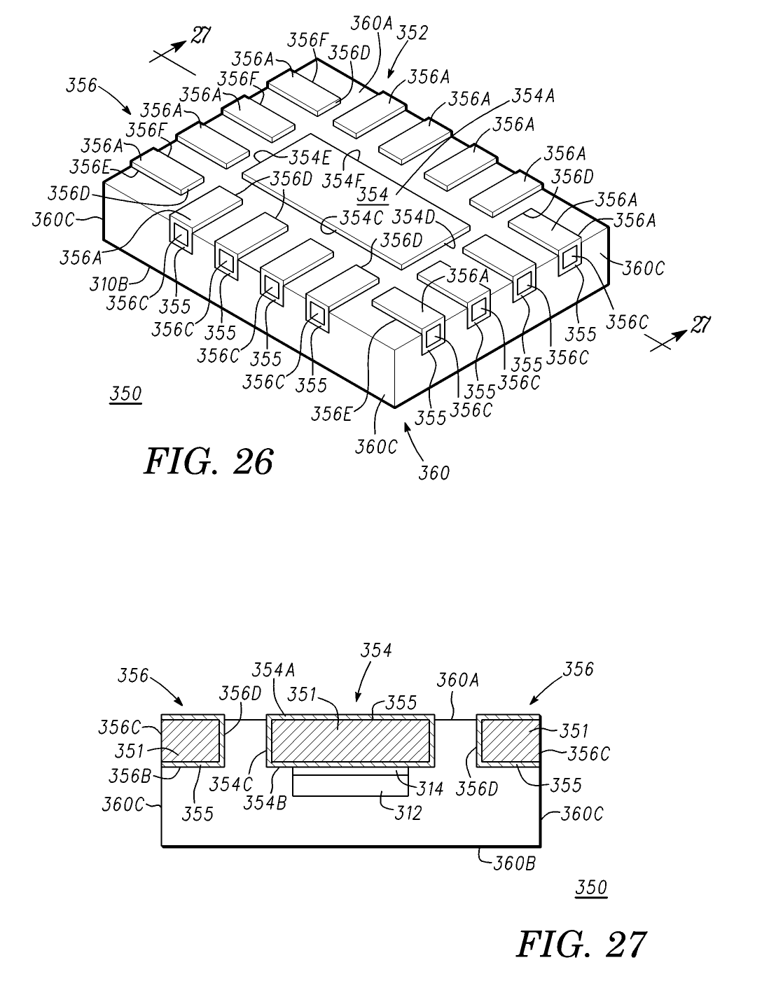

FIG. 26 is an isometric view of a semiconductor component 350 during manufacture in accordance with another embodiment of the present invention. FIG. 27 is a cross-sectional view of semiconductor component 350 taken along section line 27-27 of FIG. 26. For the sake of clarity, FIGS. 26 and 27 will be described together. FIGS. 26 and 27 illustrate a portion of an electrically conductive support 352 that includes a device or component receiving structure 354 and interconnect structures 356 partially embedded in a mold compound 360. In accordance with an embodiment, electrically conductive support 352 is a portion of a leadframe 351 such as, for example, leadframe 51 described with reference to FIG. 4 that is coated with an electrically conductive material 355. In accordance with an embodiment, layer of electrically conductive material 355 is formed on leadframe 351 to form electrically conductive support structure 352 having device or component receiving structure 354 and interconnect structures 356. By way of example, electrically conductive layer 355 is electroplated onto leadframe 351. Suitable materials for electrically conductive layer 355 include nickel, palladium, gold, or the like. Device receiving structure 354 has opposing major surfaces 354A and 354B and minor surfaces 354C, 354D, 354E, and 354F. Minor surfaces 354C-354F may be referred to as edges. Major surface 354B serves as a device attach or device receiving area.

Semiconductor component 350 is singulated from a molded leadframe strip (described with reference to FIG. 20) using a sawing technique and may be referred to as outer edges of the interconnect structure. Thus, surfaces 356C of interconnect structures 356 are substantially planar with corresponding minor surfaces 360C of mold compound 360. Surfaces 356C are on one side of semiconductor component 350 and surfaces 356D are on a side opposite to the side on which surfaces 356C are located. Because semiconductor component 350 has been singulated from a molded leadframe strip, surfaces 356C are comprised of the copper of leadframe 351 surrounded by electrically conductive layer 355.

Interconnect structures 356 have opposing major surfaces 356A and 356B and minor surfaces 356C, 356D, 356E, and 356F. In accordance with embodiments in which electrically conductive support 352 is a leadframe, device receiving structure 354 may be referred to as a flag, die attach paddle, or die attach pad and interconnect structures 356 may be referred to as leadframe leads. The distance between major surface 354A and major surface 354B is referred to as a thickness of device receiving structure 354. The distance between major surface 356A and major surface 356B may be referred to as the thickness of leadframe leads 356. Electrically conductive support 352 is embedded in mold compound 360, which mold compound 360 has major surfaces 360A and 360B and minor surfaces 360C. In accordance with an embodiment, at least 20 percent (%) of the thickness of electrically conductive support 352 is embedded in mold compound 360. In accordance with another embodiment, at least 50% of the thickness of electrically conductive support 352 is embedded in mold compound 360. In accordance with yet another embodiment, at least 90% of the thickness of electrically conductive support 352 is embedded in mold compound 360. It should noted that the amount of material embedded in mold compound 360 should be enough to secure conductive support 352 in mold compound 360. It should further noted that surfaces 354A and 356A are vertically spaced apart from surface 360A.

FIG. 27 further illustrates a semiconductor chip or die 312 mounted to device receiving area 354B. More particularly, a die attach material 314 is deposited on device receiving area 354B and a semiconductor chip 312 is positioned on die attach material 314. Semiconductor chip 312 is shown as being mounted to device receiving are 354B through a die attach material 314.

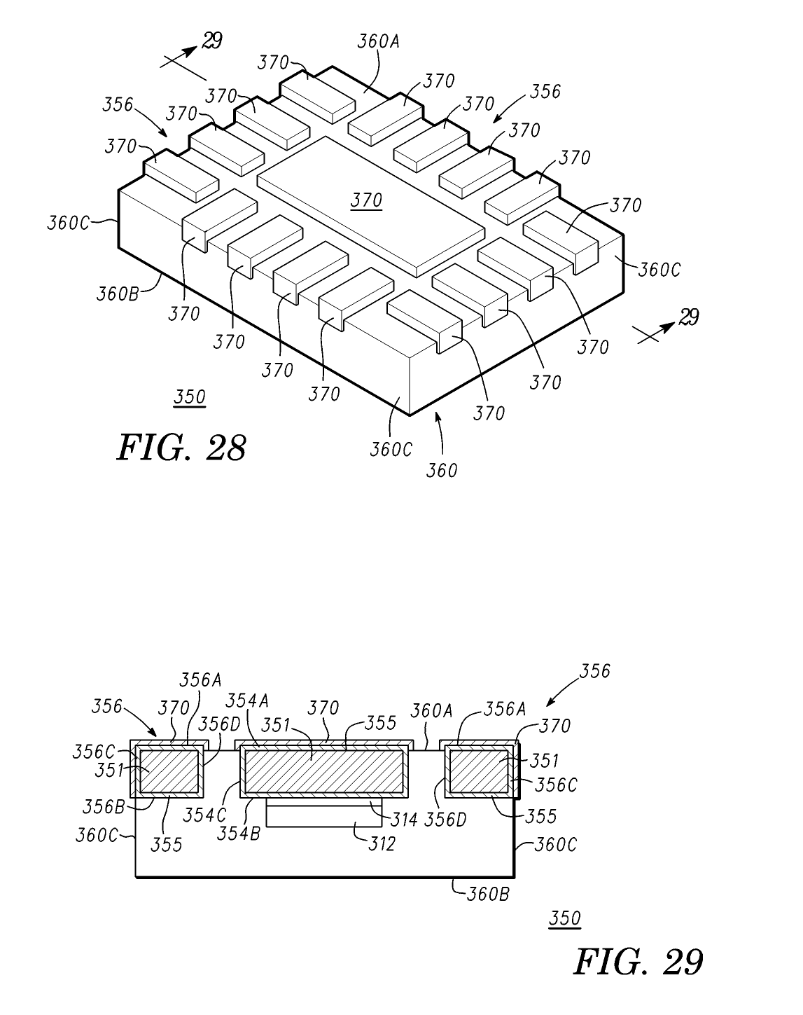

FIG. 28 is an isometric view of semiconductor component 350 shown in FIGS. 24 and 25 at a later stage of manufacture. FIG. 29 is a cross-sectional view of semiconductor component 350 taken along section line 29-29 of FIG. 28. For the sake of clarity, FIGS. 28 and 29 will be described together. A layer of electrically conductive material 370 is formed on the exposed portions of device receiving structure 354 and interconnect structures 356, i.e., on the exposed portions of surfaces 354A and 354C-354F of device receiving structure 354 and on surfaces 356A and 356C-356F of interconnect structures 356. Electrically conductive material 370 is not formed on the portions of device receiving area 354 and interconnect structures 356 within or surrounded by mold compound 360. Electrically conductive layers 370 are formed using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 370 may be referred to as a spouted bed electroplated material when formed using a spouted bed electroplating device or a vibratory plated material when formed using a vibratory plating device. By way of example, the spouted bed electroplated material or the vibratory plated material may have a thickness of at least about 2 μm and may be formed on up to one hundred percent of a surface 356C of the least one of the interconnect structures 356. Layers 370 are further illustrated in FIG. 29. In accordance with an embodiment, the material of electrically conductive layer 370 is tin. The material of electrically conductive layer 370 is not a limitation of the present invention. Other suitable materials for electrically conductive layer 370 include lead; solder; a combination of tin and lead; silver; nickel; a combination of nickel, lead, and gold; or the like. Similarly, the method for forming electrically conductive layer 370 is not a limitation of the present invention. Layer of electrically conductive material 370 may cover or partially cover surfaces 356C-356F. An advantage of forming layer of electrically conductive material 370 is that it forms a wettable material over surfaces 356C-356F that is useful in mounting the semiconductor component in end user applications.

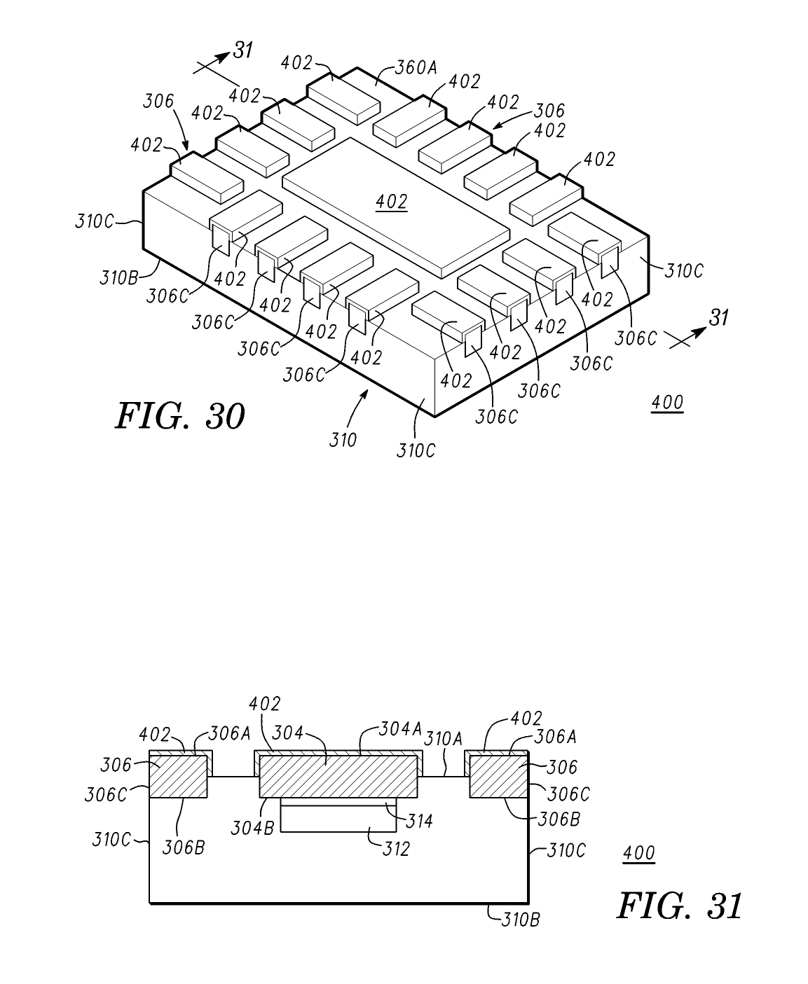

FIG. 30 is an isometric view of a semiconductor component 400 during manufacture in accordance with another embodiment of the present invention. FIG. 31 is a cross-sectional view of semiconductor component 400 taken along section line 31-31 of FIG. 30. For the sake of clarity, FIGS. 30 and 31 will be described together. The manufacture of semiconductor component 400 is similar to that of semiconductor component 300 described with reference to FIGS. 22 and 23. Accordingly, the description of FIG. 30 continues from the description of FIGS. 22 and 23. A layer of electrically conductive material 402 is formed over device or component receiving structure 304 and interconnect structures 306. Electrically conductive material 402 may be tin, lead, solder, a combination of tin and lead, or the like. Electrically conductive material 402 is absent from end surfaces 306C of interconnect structures 306. Thus, end surfaces 306C are exposed regions of interconnect structures 306. When interconnect structures 306 are copper, end surfaces 306C are exposed regions of copper. By way of example, end surfaces 306C are exposed when semiconductor components 400 are separated or singulated from a leadframe strip (not shown) using a sawing technique and may be referred to as outer edges of the leadframe lead. Because interconnect structures 306 are singulated using a sawing technique, surfaces 306C of interconnect structures 306 are substantially planar with corresponding minor surfaces 310C of mold compound 310.

FIG. 31 further illustrates die attach pad or flag 304, leadframe leads 306, and electrically conductive layer 402. For the sake of completeness, a semiconductor chip 312 is shown as being mounted to leadframe flag 304B through a die attach material 314.

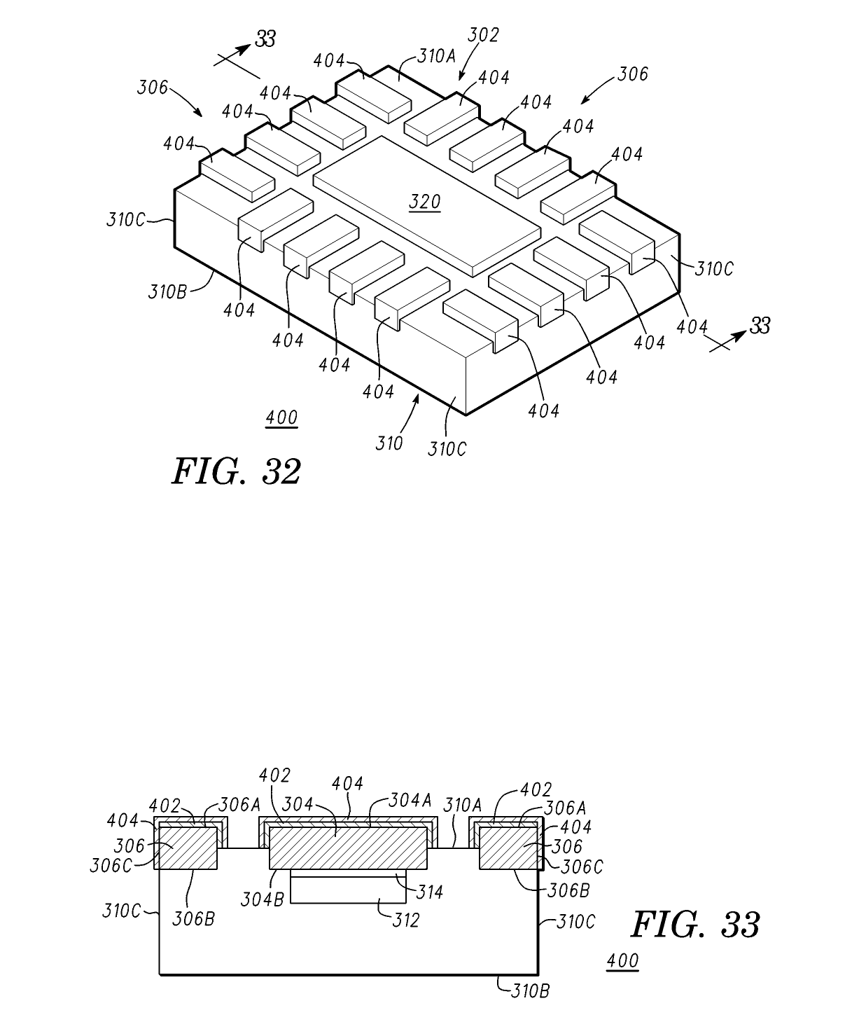

Referring now to FIG. 32, an electrically conductive material 404 is formed on electrically conductive layer 402 and on end surfaces 306A using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 404 may be referred to as vibratory plated material or the spouted bed electroplated material when formed using a vibratory plating device or a spouted bed electroplating device, respectively, and may be formed on up to one hundred percent of the outer edge of the least one of the plurality of leads. Layers 404 are further illustrated in FIG. 33. In accordance with an embodiment, the material of electrically conductive layer 404 is tin. The material of electrically conductive layer 404 is not a limitation of the present invention. Other suitable materials for electrically conductive layer 404 include lead; solder; a combination of tin and lead; silver; nickel; a combination of nickel, lead, and gold; or the like. Similarly, the method for forming electrically conductive layer 404 is not a limitation of the present invention. Layer of electrically conductive material 404 may cover or partially cover surfaces 306C. An advantage of forming layers of electrically conductive material 404 is that it forms a wettable material over surfaces 306C.

FIG. 33 is a cross-sectional view of semiconductor component 10 taken along section line 33-33 of FIG. 32. FIG. 33 further illustrates device receiving structure 304, interconnect structures 306, and electrically conductive layers 404. For the sake of completeness, a semiconductor chip 312 is shown as being mounted to device receiving structure 304 through a die attach material 314.

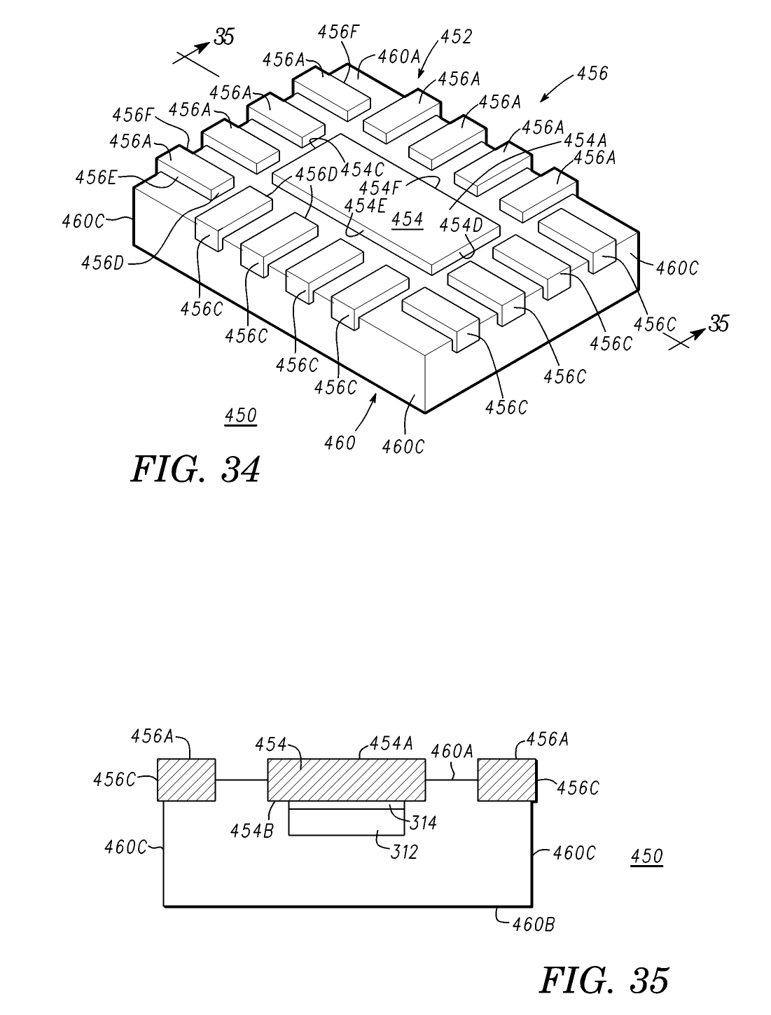

FIG. 34 is an isometric view of a semiconductor component 450 during manufacture in accordance with another embodiment of the present invention. FIG. 35 is a cross-sectional view of semiconductor component 450 taken along section line 35-35 of FIG. 34. For the sake of clarity, FIGS. 34 and 35 will be described together. FIGS. 34 and 35 illustrate a portion of an electrically conductive support 452 that includes a device or component receiving structure 454 and interconnect structures 456 partially embedded in a mold compound 460. In accordance with an embodiment, electrically conductive support 452 is a portion of a leadframe such as, for example, leadframe 51 described with reference to FIG. 4. Device receiving structure 454 has opposing major surfaces 454A and 454B and minor surfaces 454C, 454D, 454E, and 454F. Minor surfaces 454C-454F may be referred to as edges. Major surface 454B serves as a device attach or device receiving area. Interconnect structures 456 have opposing major surfaces 456A and 456B and minor surfaces 456C, 456D, 456E, and 456F. Surfaces 456C are on one side of semiconductor component 450 and surfaces 456D are on a side opposite to the side on which surfaces 456C are located. In accordance with embodiments in which electrically conductive support 452 is a leadframe, device receiving structure 454 may be referred to as a flag, a die attach paddle, or a die attach pad, and interconnect structures 456 may be referred to as leadframe leads. The distance between major surface 454A and major surface 454B is referred to as a thickness of device receiving structure 454. The distance between major surface 456A and major surface 456B may be referred to as the thickness of leadframe lead 456. Electrically conductive support 452 is embedded in a mold compound 460, which mold compound 460 has major surfaces 460A and 460B and minor surfaces 460C. In accordance with an embodiment, at least 20 percent (%) of the thickness of electrically conductive support 452 is embedded in mold compound 460. In accordance with another embodiment, at least 50% of the thickness of electrically conductive support 452 is embedded in mold compound 460. In accordance with yet another embodiment, at least 90% of the thickness of electrically conductive support 452 is embedded in mold compound 460. It should noted that the amount of material embedded in mold compound 460 should be enough to secure conductive support 452 in mold compound 460. It should further noted that surfaces 454A and 456A are vertically spaced apart from surface 460A.

FIG. 35 further illustrates a semiconductor chip or die 312 mounted to device receiving area 454B of die attach paddle 454. More particularly, a die attach material 314 is deposited on device receiving area 454B and a semiconductor chip 312 is positioned on die attach material 314 so that semiconductor chip 312 is mounted to device receiving area 454B of die attach paddle through a die attach material 314.

It should be understood that semiconductor component 450 is a single component that has been singulated from a molded leadframe strip (described with reference to FIG. 20) using a trim technique. A trim technique may leave surfaces 456C of leadframes 456 protruding from corresponding surfaces 460C of mold compound 460, i.e., surfaces 456C of leadframe leads 456 are spaced apart from corresponding surfaces 460C of mold compound 460.

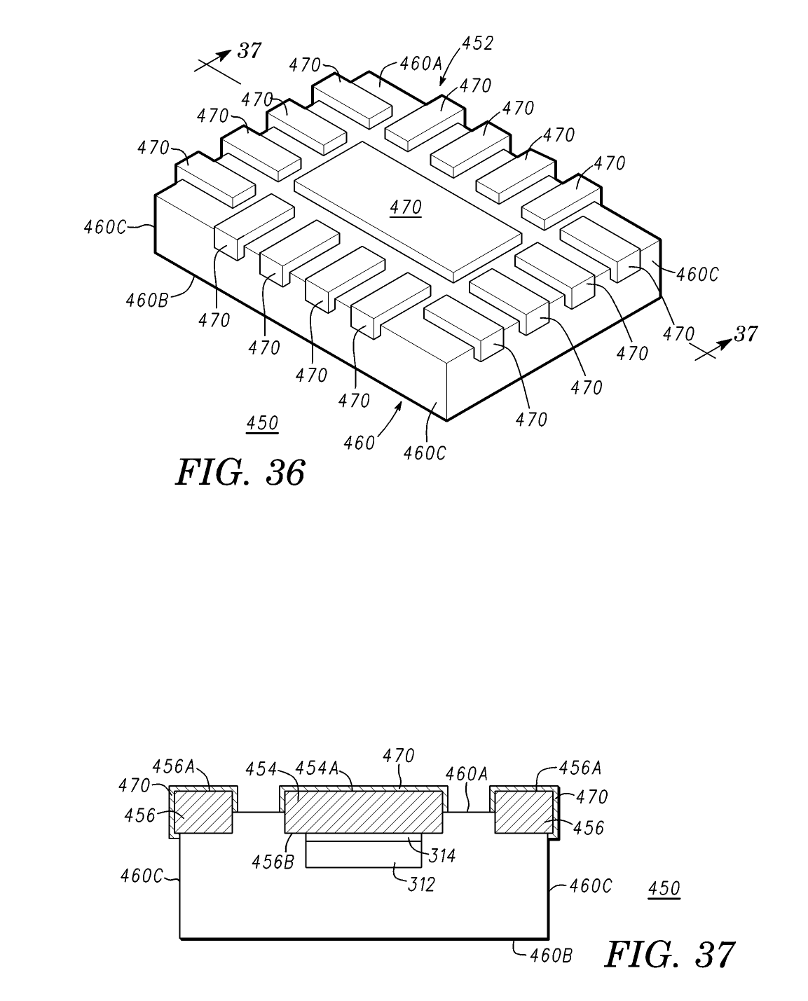

FIG. 36 is an isometric view of semiconductor component 450 shown in FIGS. 34 and 35 at a later stage of manufacture. FIG. 37 is a cross-sectional view of semiconductor component 450 taken along section line 37-37 of FIG. 36. For the sake of clarity, FIGS. 36 and 37 will be described together. A layer of electrically conductive material 470 is formed on the exposed portions of device receiving structure 454 and interconnect structures 456, i.e., on the exposed portions of surfaces 454A and 454C-454F. Electrically conductive material 470 is not formed on the portions of device receiving area 454 and interconnect structures 456 within or surrounded by mold compound 460. Electrically conductive layers 470 are formed using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 470 may be referred to as a spouted bed electroplated material when formed using a spouted bed electroplating device for its formation or a vibratory plated material when formed using a vibratory plating device for its formation. By way of example, the spouted bed electroplated material or the vibratory plated material may have a thickness at least about 2 micrometers (μm) and may be formed on up to one hundred percent of a surface 456C of least one of the interconnect structures 456. Layers 470 are further illustrated in FIG. 37, which figure shows that after plating, layers 470 on surface 456C extend further out of the plane formed by surface 460C.

In accordance with an embodiment, the material of electrically conductive layer 470 is tin. The material of electrically conductive layer 470 is not a limitation of the present invention. Other suitable materials for electrically conductive layer 470 include lead; solder; a combination of tin and lead; silver; nickel; a combination of nickel, lead, and gold; or the like. Similarly, the method for forming electrically conductive layer 470 is not a limitation of the present invention. Layer of electrically conductive material 470 may cover or partially cover surfaces 456C-456F. An advantage of forming layer of electrically conductive material 470 is that it forms a wettable material over edges or surface 456C-456F that is useful in mounting the semiconductor component in end user applications.

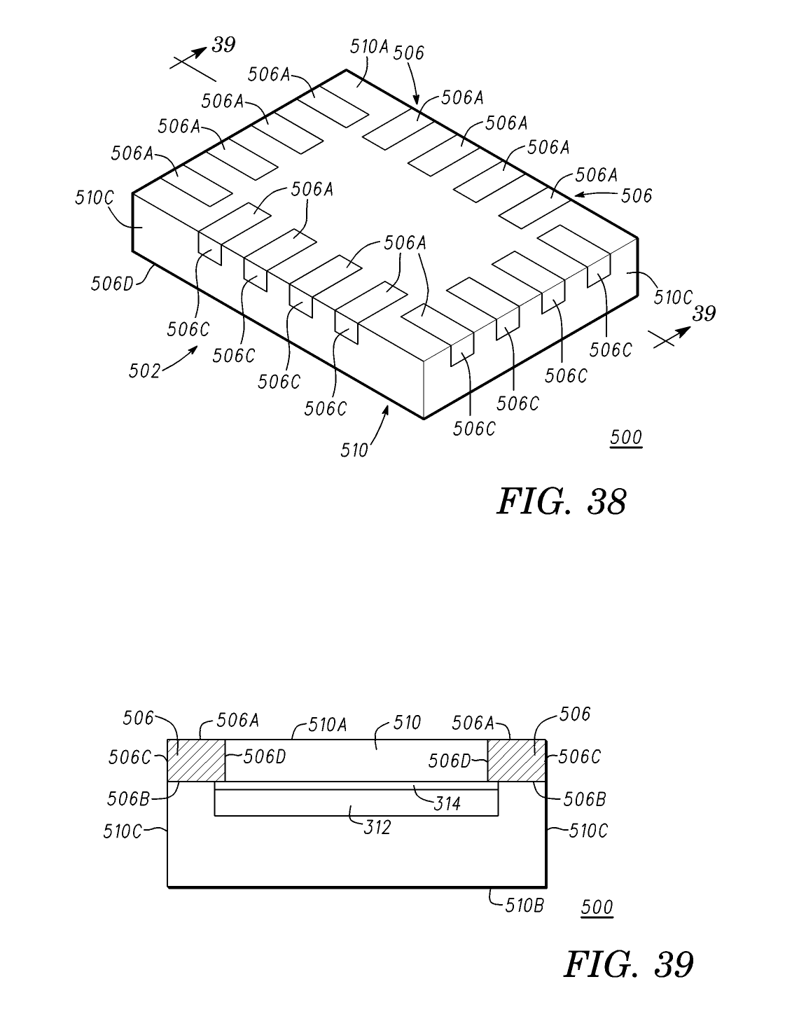

FIG. 38 is an isometric view of a semiconductor component 500 during manufacture in accordance with another embodiment of the present invention. FIG. 39 is a cross-sectional view of semiconductor component 500 taken along section line 39-39 of FIG. 38. For the sake of clarity, FIGS. 38 and 39 will be described together. FIGS. 38 and 39 illustrate a portion of an electrically conductive support 502 that includes interconnect structures 506 partially embedded in a mold compound 510. In accordance with an embodiment, electrically conductive support 502 is a portion of a leadframe that does not include a flag or die attach paddle. Interconnect structures 506 have opposing major surfaces 506A and 506B and minor surfaces 506C and 506D. It should be noted that interconnect structure 506 has surfaces that are perpendicular to surfaces 506C and 506D that are not shown because they are embedded in mold compound 510. In accordance with embodiments in which electrically conductive support 502 is a leadframe, interconnect structures 506 may be referred to as leadframe leads. The distance between major surface 506A and major surface 506B may be referred to as the thickness of leadframe lead 506. Electrically conductive support 502 is partially embedded in a mold compound 510, which mold compound 510 has major surfaces 510A and 510B and minor surfaces 510C. Support structures 506 are embedded within mold compound 510 such that surfaces 506A of support structure 506 are planar with surface 510A of mold compound 510 and surfaces 506C of support structure 506 are planar with surface 510C of mold compound 510. Because surfaces 506A are exposed and planar with surface 510A and surfaces 506C are exposed and planar with corresponding surfaces 510C, electrically conductive support 502 may be considered as being partially embedded within mold compound 510.

FIG. 39 further illustrates a semiconductor chip or die 312 mounted to support structures 506. More particularly, a die attach material 314 is deposited on a surface of a semiconductor chip 312 and semiconductor chip 312 mounted to interconnect structures 506.

It should be understood that semiconductor component 500 is a single component that has been singulated from a molded leadframe strip (similar to that described with reference to FIG. 20, but without die attach paddles) using a sawing technique.

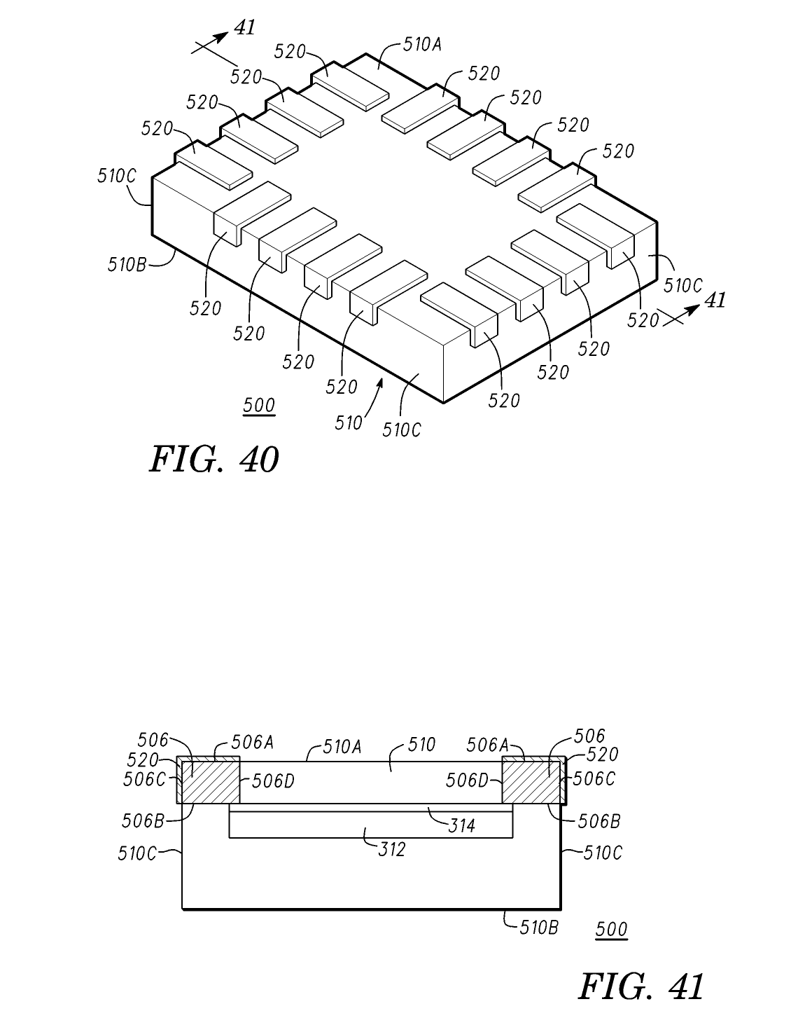

FIG. 40 is an isometric view of semiconductor component 500 shown in FIGS. 38 and 39 at a later stage of manufacture. FIG. 41 is a cross-sectional view of semiconductor component 500 taken along section line 41-41 of FIG. 40. For the sake of clarity, FIGS. 40 and 41 will be described together. A layer of electrically conductive material 520 is formed on the exposed portions of interconnect structures 506, i.e., on surfaces 506A and 506C. Electrically conductive material 520 is not formed on the portions of interconnect structures 506 within or surrounded by mold compound 520. Electrically conductive layers 520 are formed using, for example, an electroplating process such as a spouted bed electroplating process or a vibratory plating process. The spouted bed electroplating process may be performed in a spouted bed electroplating device and the vibratory plating process may be performed in a vibratory plating device. Electrically conductive material 520 may be referred to as a spouted bed electroplated material when formed using a spouted bed electroplating device for its formation or a vibratory plated material when formed using a vibratory plating device for its formation. By way of example, the spouted bed electroplated material or the vibratory plated material may have a thickness at least about 2 micrometers (μm) and may be formed on up to one hundred percent of a surfaces 506A and 506C of least one of the interconnect structures 506. Layers 520 are further illustrated in FIG. 41, which figure shows that after plating, layers 520 on surfaces 506A extend further out of the plane formed by surface 510A and surfaces 506C extend further out of the plane formed by surface 510C.

In accordance with an embodiment, the material of electrically conductive layer 520 is tin. The material of electrically conductive layer 520 is not a limitation of the present invention. Other suitable materials for electrically conductive layer 520 include lead; solder; a combination of tin and lead; silver; nickel; a combination of nickel, lead, and gold; or the like. Similarly, the method for forming electrically conductive layer 520 is not a limitation of the present invention. Layer of electrically conductive material 520 may cover or partially cover surfaces 506A and 506C. An advantage of forming layer of electrically conductive material 520 is that it forms a wettable material over edges or surface 506A and 506C that is useful in mounting the semiconductor component in end user applications.

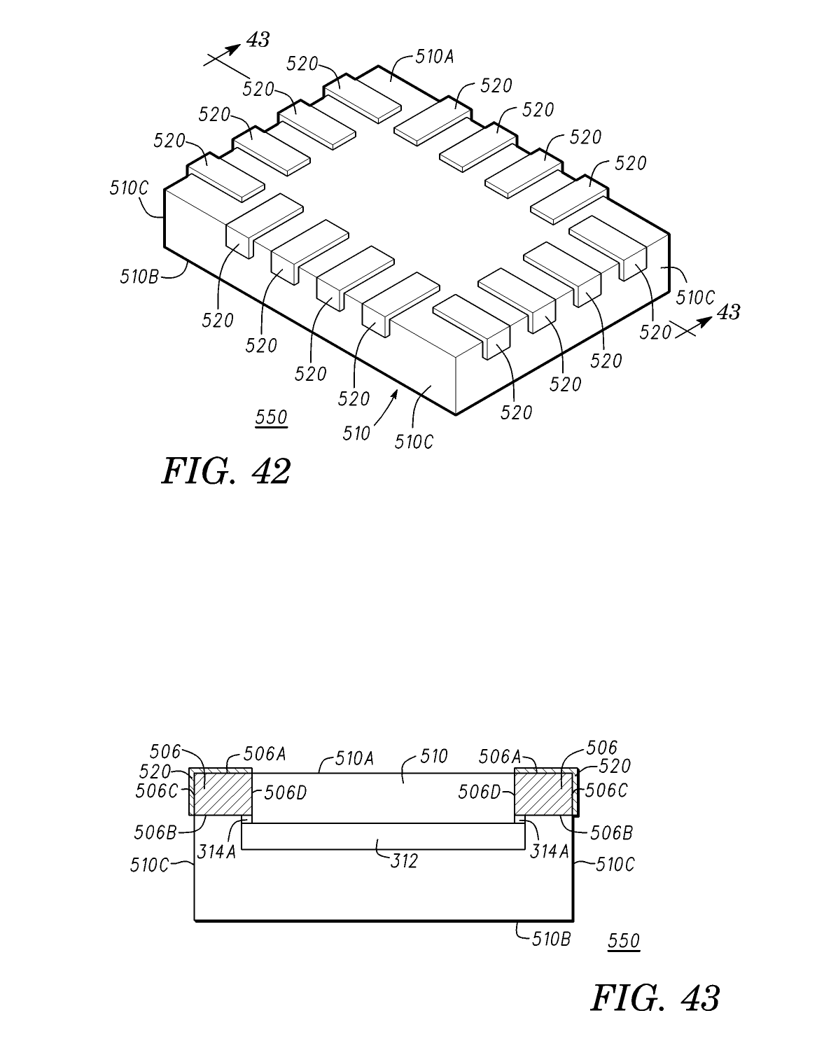

FIG. 42 is an isometric view of a semiconductor component 550 during manufacture in accordance with another embodiment of the present invention. FIG. 43 is a cross-sectional view of semiconductor component 550 taken along section line 43-43 of FIG. 42. For the sake of clarity, FIGS. 42 and 43 will be described together. FIGS. 42 and 43 are similar to FIGS. 40 and 41, respectively, except that semiconductor die 312 is mounted to electrical interconnects 506 using a flip-chip technique. Thus, bond pads 315 that are formed on a surface of semiconductor die 312 are mounted to corresponding electrical interconnects 506 using die attach material 314A. Externally, semiconductor component 550 looks the same as semiconductor component 500.

Although certain preferred embodiments and methods have been disclosed herein, it will be apparent from the foregoing disclosure to those skilled in the art that variations and modifications of such embodiments and methods may be made without departing from the spirit and scope of the invention. For example, the electrically conductive support structure may be a flagless structure. It is intended that the invention shall be limited only to the extent required by the appended claims and the rules and principles of applicable law.

What is claimed is:

1. A method for manufacturing a semiconductor component, comprising:
providing a semiconductor support structure partially embedded in a mold compound, the semiconductor support structure having a plurality of interconnect structures;
exposing a first edge of at least one interconnect structure of the plurality of interconnect structures; and
electroplating a first material over a portion of the first edge using one of a spouted bed electroplating device or a vibratory plating device.

2. The method of claim 1, wherein exposing the first edge comprises sawing the at least one interconnect structure of the plurality of interconnect structures.

3. The method of claim 1, wherein exposing the first edge comprises etching the at least one interconnect structure of the plurality of interconnect structures.

4. The method of claim 1, wherein exposing the first edge comprises trimming the at least one interconnect structure of the plurality of interconnect structures.

5. The method of claim 1, wherein providing the semiconductor support structure partially embedded in the mold compound includes providing the semiconductor support structure with a die attach paddle, and further including mounting a semiconductor chip to the die attach paddle.

6. The method of claim 1, further including mounting a semiconductor chip to the at least one interconnect structure of the plurality of interconnect structures.

7. The method of claim 6, wherein mounting the semiconductor chip to the at least one interconnect structure of the plurality of interconnect structures includes flip-chip mounting the semiconductor chip to the at least one interconnect structure.

8. The method of claim 1, further including forming a second material over the semiconductor support before exposing the first edge of the at least one interconnect structure of the plurality of interconnect structures.

9. The method of claim 8, further including forming a second material over the semiconductor support before partially embedding the semiconductor support in the mold compound.

10. A method for manufacturing a semiconductor component, comprising:
providing a leadframe having first and second major surfaces and a plurality of leadframe leads, wherein a first leadframe lead of the plurality of leadframe leads extends from a first side of the leadframe;
embedding the leadframe in a mold compound to form a molded leadframe lead, the mold compound having a first edge at the first side, wherein the first leadframe lead extends from the first edge of the first side;
removing a portion of the first leadframe lead, wherein an exposed surface of the first leadframe lead remains after removing the portion of the first leadframe lead; and
electroplating an electrically conductive material over the exposed portion of the first edge using spouted bed electroplating process or a vibratory plating process.

11. The method of claim 10, wherein providing the leadframe includes providing the leadframe having a layer of metal formed thereon.

12. The method of claim 11, wherein removing the portion of the first leadframe lead includes leaving the exposed surface of the leadframe and an exposed surface of the layer of metal formed on the leadframe.

13. The method of claim 10, wherein providing the leadframe includes providing a leadframe having a die attach paddle.

14. The method of claim 13, wherein providing the leadframe includes mounting a semiconductor die to the leadframe before embedding the leadframe in the mold compound.

15. The method of claim 13, wherein removing the portion of the first leadframe lead leaves the exposed surface of the first lead planar with the first edge of the mold compound.

16. The method of claim 13 wherein removing the portion of the first leadframe lead leaves the exposed surface of the first lead nonplanar with the first edge of the mold compound.

17. The method of claim 13, further including forming a layer of metal over the plurality of leadframe leads before removing the portion of the first leadframe lead.

18. A semiconductor component, comprising:
a semiconductor device coupled to an electrical interconnect structure, wherein the semiconductor device is embedded in a mold compound and the electrical interconnect structure is partially embedded in the mold compound, and wherein the electrical interconnect structure comprises a plurality of leads, each lead having an outer edge; and
a vibratory plated material or a spouted bed electroplated material over a portion of the outer edge of at least one of the plurality of leads, the vibratory plated material or the spouted bed electroplated material over a portion of the outer edge of the least one of the plurality of leads.

19. The semiconductor component of claim 18, wherein the vibratory plated material or the spouted bed electroplated material is the vibratory plated material over the portion of the outer edge of at least one of the plurality of leads.

20. The semiconductor component of claim 18, wherein the vibratory plated material or the spouted bed electroplated material is the spouted bed plated material over the portion of the outer edge of at least one of the plurality of leads.
